(19) United States
(12) Patent Application Publication
(10) Pub. No.: US 2026/0343867 A1
(43) Pub. Date: Oct. 29, 2026

(54) THREE DIMENSIONAL DYNAMIC RANDOM ACCESS MEMORY AND MANUFACTURING METHOD THEREOF

(71) Applicant: SAMSUNG ELECTRONICS CO., LTD., Suwon-si (KR)

(72) Inventors: Kyunghwan LEE, Suwon-si (KR); Daewon HA, Suwon-si (KR); Hwayeong LEE, Suwon-si (KR); Seungmin LEE, Suwon-si (KR); Mintae RYU, Suwon-si (KR); Youngin GOH, Suwon-si (KR)

(73) Assignee: SAMSUNG ELECTRONICS CO., LTD., Suwon-si (KR)

(21) Appl. No.: 19/716,510

(22) Filed: Jun. 23, 2026

(30) Foreign Application Priority Data
Sep. 1, 2025 (KR) 10-2025-0123525

(51) Int. Cl. H10B 12/00

(52) U.S. Cl. CPC H10B 12/488; H10B 12/02

(57) ABSTRACT

A three-dimensional (3D) dynamic random access memory (DRAM) includes a first stack separation insulating layer and a second stack separation insulating layer spaced apart from each other in a first horizontal direction, at least one partial-separation insulating layer alternately arranged among a plurality of memory cell regions and extending in a second horizontal direction perpendicular to the first horizontal direction, a region separation insulating layer extending in the first horizontal direction between the plurality of memory cell regions and a connection region. Each of the plurality of memory cell regions includes a common word line surrounded by a first semiconductor layer and a second semiconductor layer and covering a side wall of a cell mold layer. The connection region includes a word line pad having a liner shape and a word-line contact plug in contact with an inner wall of the word line pad.

### CROSS-REFERENCE TO RELATED APPLICATION

This application is based on and claims priority under 35 U.S.C. § 119 to Korean Patent Application No. 10-2025-0123525, filed on Sep. 1, 2025, in the Korean Intellectual Property Office, the disclosure of which is incorporated by reference herein in its entirety.

### BACKGROUND

The disclosure relates to a semiconductor memory device, and particularly to, a three-dimensional (3D) dynamic random-access memory (DRAM) and a manufacturing method of manufacturing the same.

With the demands for miniaturization, multi-functionality, and high performance of electronic products, high-capacity semiconductor memory devices are needed, and in order to provide high-capacity semiconductor memory devices, increased integration is needed. As the integration density of conventional two-dimensional (2D) semiconductor memory devices is mainly determined by an area occupied by a unit memory cell, the integration density of the 2D semiconductor memory devices is increasing but remains limited. Accordingly, 3D semiconductor memory devices have been proposed in which a plurality of memory cells are stacked in a vertical direction on a substrate so that memory capacity is increased.

### SUMMARY

The disclosure provides a three-dimensional (3D) dynamic random-access memory (DRAM) having an improved DRAM cell integration density.

The disclosure provides a 3D DRAM in which parasitic capacitance between a plurality of word line pads stacked in a vertical direction is reduced.

Furthermore, the technical objectives to be achieved by the disclosure are not limited to the above-described objective, and other technical objectives that are not mentioned herein would be clearly understood by a person skilled in the art from the description of the disclosure.

According to an aspect of the disclosure, there is provided a 3D DRAM including a substrate, a first stack separation insulating layer and a second stack separation insulating layer both disposed on the substrate and spaced apart from each other in a first horizontal direction, at least one partial-separation insulating layer, on the substrate, arranged between the first stack separation insulating layer and the second stack separation insulating layer, and extending in a second horizontal direction perpendicular to the first horizontal direction, a plurality of memory cell regions alternately arranged with the first stack separation insulating layer, the at least one partial-separation insulating layer, and the second stack separation insulating layer, a separation insulating layer, on the substrate, arranged between the first stack separation insulating layer and the second stack separation insulating layer and extending in the first horizontal direction region between the plurality of memory cell regions and a connection region, the plurality of memory cell regions and the connection region being arranged in the second horizontal direction. Each of the plurality of memory cell regions includes a first semiconductor layer and a second semiconductor layer spaced apart from each other in the first horizontal direction and facing each other, a first bit line and a first capacitor both in contact with the first semiconductor layer, spaced apart from each other in the second horizontal direction, a second bit line and a second capacitor both in contact with the second semiconductor layer, spaced apart from each other in the second horizontal direction, a cell mold layer surrounding the first bit line, the first capacitor, the second bit line, and the second capacitor, and a common word line surrounded by the first semiconductor layer and the second semiconductor layer and covering a side wall of the cell mold layer, and the connection region includes a connection mold layer, a word line pad covering a side wall of the connection mold layer and having a liner shape, and a word-line contact plug penetrating the connection mold layer and in contact with an inner wall of the word line pad.

Furthermore, according to another aspect of the disclosure, there is provided a 3D DRAM including a substrate, a first stack separation insulating layer and a second stack separation insulating layer spaced apart from each other in the first horizontal direction, on the substrate, at least one partial-separation insulating layer, on the substrate, arranged between the first stack separation insulating layer and the second stack separation insulating layer, and extending in a second horizontal direction perpendicular to the first horizontal direction, a plurality of memory cell regions alternately arranged with the first stack separation insulating layer, the at least one partial-separation insulating layer, and the second stack separation insulating layer, a first region separation insulating layer, on the substrate, extending from the first stack separation insulating layer in the first horizontal direction and arranged between the plurality of memory cell regions and a connection region, the plurality of memory cell regions and the connection region being arranged in the second horizontal direction, and a second region separation insulating layer extending from the second stack separation insulating layer in the first horizontal direction and arranged between the plurality of memory cell regions and the connection region, in which each of the plurality of memory cell regions includes a first semiconductor layer and a second semiconductor layer spaced apart from each other in the first horizontal direction and facing each other, a first bit line and a first capacitor both in contact with the first semiconductor layer, spaced apart from each other in the second horizontal direction, a second bit line and a second capacitor both in contact with the second semiconductor layer, spaced apart from each other in the second horizontal direction, a cell mold layer surrounding the first bit line, the first capacitor, the second bit line, and the second capacitor, and a common word line surrounded by the first semiconductor layer and the second semiconductor layer and covering a side wall of the cell mold layer, and the connection region includes a connection mold layer, a word line pad having a liner shape surrounding a side wall of the connection mold layer, and a word-line contact plug penetrating the connection mold layer and in contact with an inner wall of the word line pad.

Furthermore, according to another aspect of the disclosure, there is provided a 3D DRAM including a substrate, a plurality of memory cell regions, a first stack separation insulating layer and a second stack separation insulating layer spaced apart from each other in the first horizontal direction, on the substrate, at least one partial-separation insulating layer, on the substrate, arranged between the first stack separation insulating layer and the second stack separation insulating layer, and extending between the plurality of memory cell regions in a second horizontal direction perpendicular to the first horizontal direction, a region separation insulating layer, on the substrate, arranged between the first stack separation insulating layer and the second stack separation insulating layer, and extending between the plurality of memory cell regions and a connection region in the first horizontal direction, the plurality of memory cell regions and the connection region being arranged in the second horizontal direction, in which each of the plurality of memory cell regions includes a first semiconductor layer and a second semiconductor layer spaced apart from each other in the first horizontal direction and facing each other, a first bit line and a first capacitor both in contact with the first semiconductor layer, spaced apart from each other in the second horizontal direction, a second bit line and a second capacitor both in contact with the second semiconductor layer, spaced apart from each other in the second horizontal direction, a cell mold layer surrounding the first bit line, the first capacitor, the second bit line, and the second capacitor, and a common word line surrounded by the first semiconductor layer and the second semiconductor layer and covering a side wall of the cell mold layer, the connection region may include (M*N) connection mold layers arranged in M rows in the first horizontal direction, where M is a natural number greater than or equal to 2, and N columns in the second horizontal direction, where N is a natural number greater than or equal to 2, (M*N) word line pads surrounding a side wall of each of the (M*N) connection mold layers, spaced apart from each other in the vertical direction, and having a liner shape, and (M*N) word-line contact plugs in contact with inner walls of the (M*N) word line pads, and arranged in a two-dimensional array shape in the first horizontal direction and the second horizontal direction, and a connection layer number of each of the (M*N) word-line contact plugs decreases in a staircase manner in the first horizontal direction and the second horizontal direction.

### BRIEF DESCRIPTION OF THE DRAWINGS

Embodiments will be more clearly understood from the following detailed description taken in conjunction with the accompanying drawings in which:

FIG. 1 is a cross-sectional view of a three-dimensional (3D) dynamic random access memory (DRAM) according to an embodiment;

FIGS. 2A, 2B and 2C are a perspective view, an equivalent circuit diagram, and a cross-sectional view, respectively, of a memory cell region of a 3D DRAM according to an embodiment;

FIGS. 3A and 3B are a perspective view and a cross-sectional view, respectively, of a connection region of a 3D DRAM according to an embodiment;

FIG. 4 is a cross-sectional view of a 3D DRAM according to an embodiment;

FIGS. 5A, 5B, 6A, 6B, 6C, 7A, 7B, 8A, 8B, 9A, 9B, 10A, 10B, 10C, 11A, 11B, 12A, 12B, 13, 14, 15A, 15B, 16A, 16B, 17A, 17B, 17C, 17D, 18, 19A, and 19B are perspective views, plan views and cross-sectional views schematically illustrating a process of a method of manufacturing a 3D DRAM, according to an embodiment; and

FIGS. 20A, 20B, 21A, 21B, 22A, and 22B are perspective views and cross-sectional views schematically illustrating a process of a method of manufacturing a word-line contact plug, according to an embodiment.

### DETAILED DESCRIPTION OF THE EMBODIMENTS

In the following description, embodiments of the disclosure are described in detail with reference to the accompanying drawings. For like components, like reference numerals are used, and redundant descriptions thereof are omitted.

In the specification, a horizontal direction may include a first horizontal direction (X direction) and a second horizontal direction (Y direction) crossing each other. A direction crossing the first horizontal direction (X direction) and the second horizontal direction (Y direction) may be referred to as a vertical direction (Z direction). In the specification, a vertical level may be referred to a height level in the vertical direction (Z direction) of a certain component.

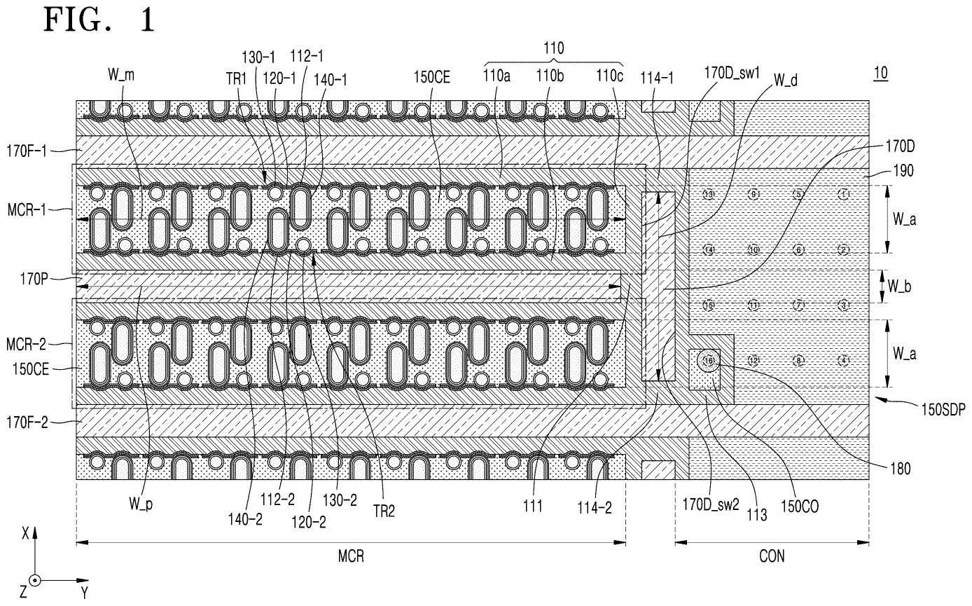

FIG. 1 is a cross-sectional view of a three-dimensional (3D) dynamic random access memory (DRAM) 10 according to an embodiment. FIG. 1 is a horizontal cross-sectional view of the 3D DRAM 10 cut in the horizontal direction at a vertical level corresponding to the 16th layer of the 3D DRAM 10 in the vertical direction.

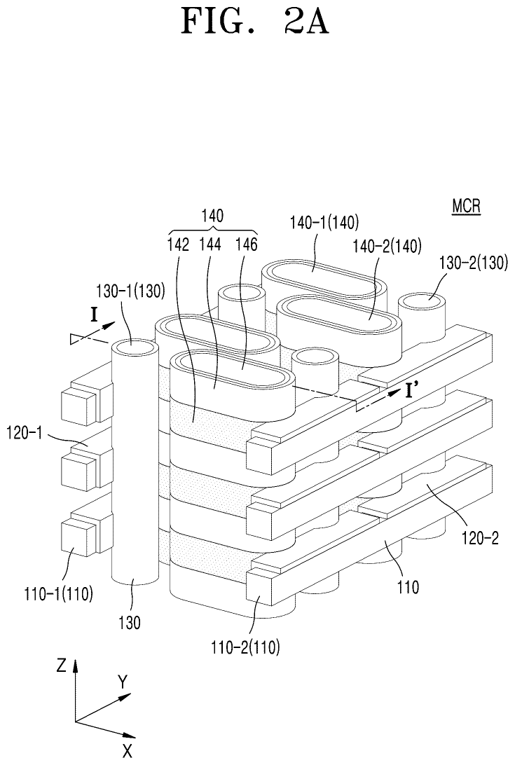

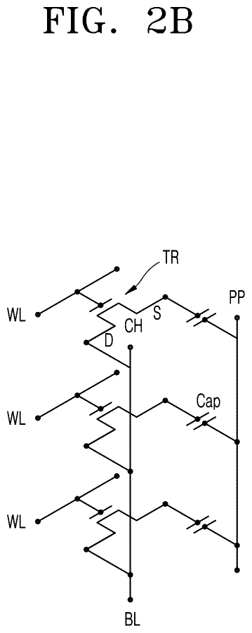

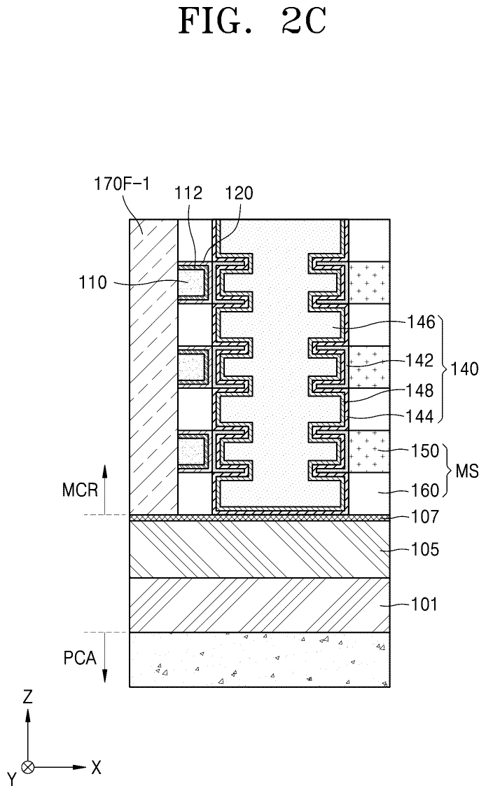

Referring to FIG. 1, the 3D DRAM 10 may include a first stack separation insulating layer 170F-1 and a second stack separation insulating layer 170F-2, which are apart from each other in a first horizontal direction. The first stack separation insulating layer 170F-1 and the second stack separation insulating layer 170F-2 may penetrate a mold structure MS (see FIG. 2C) in the vertical direction over a substrate 101 (see FIG. 2C), a base insulating layer 105 (see FIG. 2C), and an etching stop layer 107, and may extend in a second horizontal direction.

In some embodiments, the 3D DRAM 10 may include a partial-separation insulating layer 170P that extends in the second horizontal direction between the first stack separation insulating layer 170F-1 and the second stack separation insulating layer 170F-2. Furthermore, the partial-separation insulating layers 170P may be alternately arranged among a plurality of memory cell regions (e.g., a first memory cell region MCR-1 and a second memory cell region MCR-2). As illustrated in FIG. 1, when the two memory cell regions MCR-1 and MCR-2 exist, one partial-separation insulating layer 170P may be arranged between the two memory cell regions MCR-1 and MCR-2. In some embodiments, when K memory cell regions, where K is a natural number greater than or equal to 3, are arranged in the first horizontal direction at certain intervals, K−1 partial-separation insulating layers 170P may be alternately arranged among a plurality of K memory cell regions.

In some embodiments, the 3D DRAM 10 may further include a region separation insulating layer 170D that extends in the first horizontal direction between the first stack separation insulating layer 170F-1 and the second stack separation insulating layer 170F-2. The region separation insulating layer 170D may be arranged between a memory cell region MCR and a connection region CON, and the region separation insulating layer 170D may separate the memory cell region MCR and the connection region CON from each other in the second horizontal direction. The region separation insulating layer 170D may include a first side wall 170D_sw1 and a second side wall 170D_sw2 facing each other. The first side wall 170D_sw1 may be in contact with a common word line 110, and the second side wall 170D_sw2 may be in contact with a word line pad 113.

The first memory cell region MCR-1 and the second memory cell region MCR-2 may each include a plurality of DRAM cells, each having a 1TR-1Cap structure. As the first memory cell region MCR-1 and the second memory cell region MCR-2 may have the same configuration, the following description is presented based on the first memory cell region MCR-1.

The first memory cell region MCR-1 may include a first gate insulating layer 112-1, a first semiconductor layer 120-1, a first bit line 130-1, a first capacitor 140-1, a second gate insulating layer 112-2, a second semiconductor layer 120-2, a second bit line 130-2, a second capacitor 140-2, the common word line 110, and a cell mold layer 150CE. The first gate insulating layer 112-1, the first semiconductor layer 120-1, and a first part 110A of the common word line 110 may form a first transistor TR1, and the second gate insulating layer 112-2, the second semiconductor layer 120-2, and a second part 110B of the common word line 110 may form a second transistor TR2.

A plurality of first transistors TR1 may be arranged in the second horizontal direction spaced apart from each other, and a plurality of second transistors TR2 may be arranged in the second horizontal direction spaced apart from each other. The first transistors TR1 and the second transistors TR2 may be arranged facing each other. In this example, the first bit line 130-1 and the first capacitor 140-1, both connected to the first transistor TR1, may form a folding structure. The folding structure may have, for example, a shape of “U”, and based on the first horizontal direction, a degree of protrusion of the first bit line 130-1 from the first transistor TR1 may be less than a degree of protrusion of the first capacitor 140-1. The second bit line 130-2 and the second capacitor 140-2, both connected to the second transistor TR2, may also have the same folding structure as described above.

The cell mold layer 150CE may surround the first gate insulating layer 112-1, the first semiconductor layer 120-1, the first bit line 130-1, the first capacitor 140-1, the second gate insulating layer 112-2, the second semiconductor layer 120-2, the second bit line 130-2, and the second capacitor 140-2. The common word line 110 may cover the side walls of the cell mold layer 150CE. In this example, the cell mold layer 150CE may refer to a part of a first mold layer 150 arranged in the memory cell region MCR of the entire first mold layer 150 (see FIG. 2C).

The common word line 110 may include the first part 110A, the second part 110B, and a third part 110c. The first part 110A may be surrounded by the first semiconductor layer 120-1 and the first gate insulating layer 112-1 and may extend in the second horizontal direction. The second part 110B may be surrounded by the second semiconductor layer 120-2 and the second gate insulating layer 112-2 and may extend in the second horizontal direction. The third part 110c may extend in the first horizontal direction and may be connected to both of the first part 110A and the second part 110B. The third part 110c may be in contact with the first side wall 170D_sw1 of the region separation insulating layer 170D. The components of the memory cell region MCR are described below in detail with reference to FIGS. 2A to 2C.

The connection region CON may include a step region 150SDP, word-line contact plugs 180, and a cover insulating layer 190. The step region 150SDP may include a connection mold layer 150CO and the word line pad 113. The connection mold layer 150CO may refer to a part of the first mold layer 150 arranged in the connection region CON and etched in a staircase manner, of the entire first mold layer 150 (see FIG. 2C).

A plurality of connection mold layers 150CO may be stacked in the vertical direction. In some embodiments, the width of each of the connection mold layers 150CO in the horizontal direction may decrease in a staircase manner as the vertical level increases. Reversely, as the vertical level of each of the connection mold layers 150CO decreases, the width of each of the connection mold layers 150CO in the horizontal direction may increase in a staircase manner.

In some embodiments, the connection mold layers 150CO may be arranged in a two-dimensional (2D) array of M rows in the first horizontal direction and N columns in the second horizontal direction, where M and N are natural numbers greater than or equal to 2. In this case, for example, the vertical level of each of the connection mold layers 150CO may decrease by one layer in a staircase manner in the first horizontal direction and decrease by M layers in a staircase manner in the second horizontal direction. In another example, the vertical level of each of the connection mold layers 150CO may decrease by N layers in a staircase manner in the first horizontal direction and decrease by one layer in a staircase manner in the second horizontal direction.

In a detailed example, as illustrated in FIG. 1, the connection mold layers 150CO may be arranged in a 2D array having four rows in the first horizontal direction and four columns in the second horizontal direction. In this case, the vertical level of each of the connection mold layers 150CO may decrease by one layer in a staircase manner in the first horizontal direction (e.g., 16 layers→15 layers→14 layers→13 layers), and decrease by four layers in a staircase manner in the second horizontal direction (e.g., 16 layers→12 layers→8 layers→4 layers).

The word line pad 113 may have a liner shape thinly surrounding the side walls of the connection mold layer 150CO. The word line pads 113 may be spaced apart from each other in the vertical direction. The word line pads 113 may be arranged to surround the side walls of each of the connection mold layers 150CO. The word line pads 113 may each be in contact with the second side wall 170D_sw2 of the region separation insulating layer 170D, the side wall in the first horizontal direction of the first stack separation insulating layer 170F-1, and the side wall in the first horizontal direction of the second stack separation insulating layer 170F-2.

Each of the word-line contact plugs 180 may penetrate the cover insulating layer 190 in the vertical direction so as to contact each of the word line pads 113. The cover insulating layer 190 may cover the connection mold layers 150CO and the word line pads 113 on the connection mold layers 150CO and the word line pads 113, both in a staircase shape, and surround the word-line contact plugs 180.

In some embodiments, when the connection mold layers 150CO and the word line pads 113 are arranged in a 2D array having M rows in the first horizontal direction and N columns in the second horizontal direction, the word-line contact plugs 180 may be also arranged in the form of a 2D array having M rows and N columns. In this case, the connection layer number of the word-line contact plugs 180 may increase or decrease in a staircase manner in the first horizontal direction and the second horizontal direction. In this example, the connection layer number of a particular word-line contact plug 180 may refer to the layer number of the word line pad 113 that contacts the particular word-line contact plug 180. For example, the connection layer number of the word-line contact plug 180 that contacts the word line pad 113 at the 1st layer may be “the 1st layer,” and the connection layer number of the word-line contact plug 180 that contacts the word line pad 113 at the 16th layer may be “the 16th layer.” In one embodiment, the 1st layer may refer to the lowermost layer and the 16th layer may refer to a 16th layer from the lowermost layer. As the connection layer number of the word-line contact plug 180 decreases, the thickness in the vertical direction of the word-line contact plug 180 may increase, and as the connection layer number of the word-line contact plug 180 increases, the thickness in the vertical direction of the word-line contact plug 180 may decrease.

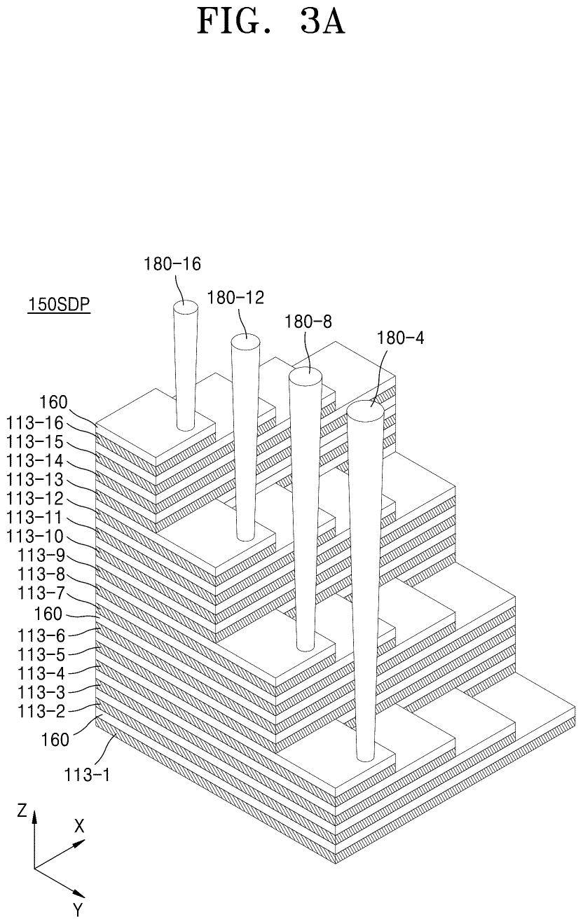

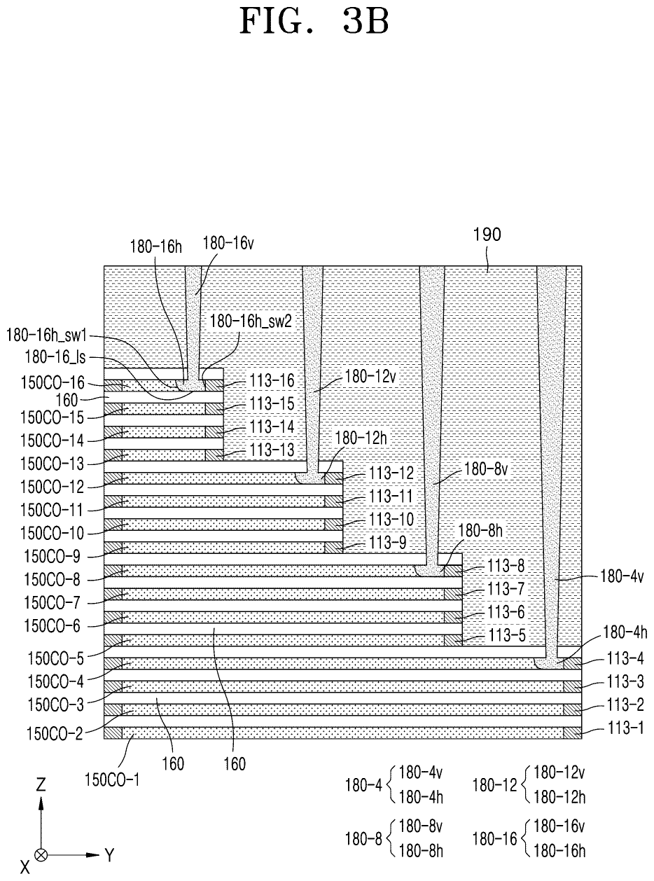

For example, the connection layer number of the word-line contact plugs 180 may decrease (or increase) by one layer in a staircase manner in the first horizontal direction, and decrease (or increase) by M layers in a staircase manner in the second horizontal direction. In another example, the connection layer number of the word-line contact plugs 180 may decrease (or increase) by N layers in a staircase manner in the first horizontal direction, and decrease (or increase) by one layer in a staircase manner in the second horizontal direction. The arrangement structure of the word-line contact plug 180, the connection mold layer 150CO, and the word line pad 113 is described below in detail with reference to FIGS. 3A and 3B.

A word line connection portion 111 may interconnect the common word lines 110 of the two memory cell regions MCR-1 and MCR-2 that are adjacent to each other. The word line connection portion 111 may be arranged between the region separation insulating layer 170D and the partial-separation insulating layer 170P. The word line connection portion 111 may extend in the first horizontal direction between the region separation insulating layer 170D and the partial-separation insulating layer 170P. For example, one end of the word line connection portion 111 in the second horizontal direction may be in contact with the first side wall 170D_sw1 of the region separation insulating layer 170D, and the other end of the word line connection portion 111 in the second horizontal direction may be in contact with the side wall of the partial-separation insulating layer 170P.

FIG. 1 illustrates that one partial-separation insulating layer 170P and one word line connection portion 111 are arranged between the two stack separation insulating layers 170F-1 and 170F-2 that are apart from each other in the first horizontal direction, but this is merely an example. In some embodiments, when K memory cell regions, where K is a natural number greater than or equal to 3, are arranged between the two stack separation insulating layers 170F-1 and 170F-2 in the first horizontal direction at certain intervals, K−1 partial-separation insulating layers 170P may be alternately arranged among the K memory cell regions, and each of the K−1 word line connection portions 111 may interconnect the common word lines 110 of each of the K memory cell regions.

A first pad connection portion 114-1 and a second pad connection portion 114-2 may connect the word line pad 113 and the common word line 110. In this example, the first pad connection portion 114-1 may connect the word line pad 113 to the common word line 110 of the first memory cell region MCR-1 that is closer to the first stack separation insulating layer 170F-1, of the memory cell regions MCR-1 and MCR-2. Furthermore, the second pad connection portion 114-2 may connect the word line pad 113 to the common word line 110 of the second memory cell region MCR-2 that is closer to the second stack separation insulating layer 170F-2, of the memory cell regions MCR-1 and MCR-2.

The first pad connection portion 114-1 may extend in the second horizontal direction between the first stack separation insulating layer 170F-1 and the region separation insulating layer 170D. One end of the first pad connection portion 114-1 in the first horizontal direction may be in contact with the first stack separation insulating layer 170F-1, and the other end of the first pad connection portion 114-1 in the first horizontal direction may be in contact with the region separation insulating layer 170D. Furthermore, one end of the first pad connection portion 114-1 in the second horizontal direction may be in contact with the third part 110c of the common word line 110 of the first memory cell region MCR-1, and the other end of the first pad connection portion 114-1 in the second horizontal direction may be in contact with the word line pad 113.

The second pad connection portion 114-2 may extend in the second horizontal direction between the second stack separation insulating layer 170F-2 and the region separation insulating layer 170D. One end of the second pad connection portion 114-2 in the first horizontal direction may be in contact with the second stack separation insulating layer 170F-2, and the other end of the second pad connection portion 114-2 in the first horizontal direction may be in contact with the region separation insulating layer 170D. Furthermore, one end of the second pad connection portion 114-2 in the second horizontal direction may be in contact with the third part 110c of the common word line 110 of the second memory cell region MCR-2, and the other end of the second pad connection portion 114-2 in the second horizontal direction may be in contact with the word line pad 113.

In some embodiments, a width W_p of the partial-separation insulating layer 170P in the second horizontal direction may be less than a width W_m of the cell mold layer 150CE in the second horizontal direction. Furthermore, a width W_b of the partial-separation insulating layer 170P in the first horizontal direction may be less than a width W_a of the cell mold layer 150CE in the first horizontal direction.

In some embodiments, a width W_d of the region separation insulating layer 170D in the first horizontal direction may be greater than or equal to a first width. In this example, the first width may be a sum of a value obtained by adding the widths W_a of the cell mold layers 150CE of the memory cell regions MCR-1 and MCR-2 in the first horizontal direction and a value obtained by adding the widths W_b of the partial-separation insulating layers 170P in the first horizontal direction. As the width W_d of the region separation insulating layer 170D in the first horizontal direction is implemented to be greater than or equal to the first width, in the manufacturing process of the 3D DRAM 10, the first pad connection portion 114-1 and the second pad connection portion 114-2 may be integrally formed with the common word line 110 and the word line pad 113. As the first pad connection portion 114-1 and the second pad connection portion 114-2 are stably formed, an electric connection between the common word line 110 and the word line pad 113 may be stably formed. A method of forming the first pad connection portion 114-1 and the second pad connection portion 114-2 is described below in detail with reference to the following drawings.

As described above, the common word lines 110 and the word line pad 113 positioned at the same layer may be connected to each other through at least one of the word line connection portion 111 and the two pad connection portions 114-1 and 114-2. An electrical connection between the common word line 110 and the word line pad 113 positioned at the same layer may be stably formed, and thus first transistors TR1 and second transistors TR2 included in the memory cell regions MCR-1 and MCR-2, respectively, may be stably driven.

Furthermore, as described above, the common word line 110 has a liner shape thinly surrounding the side walls of the cell mold layer 150CE, and the word line pad 113 may have a liner shape thinly surrounding the side walls of the connection mold layer 150CO. Accordingly, parasitic capacitance between two common word lines 110 neighboring in the vertical direction and parasitic capacitance between two word line pads 113 neighboring in the vertical direction may decrease. Generally, in a 3D memory device according to the related art, a word line in a plane shape or a word line pad in a plane shape are spaced apart from each other in the vertical direction. In this case, parasitic capacitance between two word lines or word line pads neighboring in the vertical direction increases, so that problems such as crosstalk or delay may occur. As the 3D DRAM 10 according to an embodiment includes the common word line 110 and the word line pad 113 both having a liner shape thinly surrounding the side walls of a mold layer, the problems due to the parasitic capacitance may be addressed. Furthermore, as the 3D DRAM 10, which includes at least one of the word line connection portion 111 and two pad connection portions 112-1 and 112-2, may include DRAM cells with improved integration.

FIGS. 2A, 2B and 2C are a perspective view, an equivalent circuit diagram, and a cross-sectional view, respectively, of a memory cell region MCR of the 3D DRAM 10 according to an embodiment. Referring to FIGS. 2A to 2C, the 3D DRAM 10 may include a substrate 101, a semiconductor layer 120, the common word line 110, a bit line 130, and a capacitor 140.

The substrate 101 may include silicon (Si), for example, single crystal Si, polycrystalline Si (poly-Si), or amorphous Si. The material of the substrate 101 is not limited to Si. For example, in some embodiments, the substrate 101 may include Group IV semiconductors such as germanium (Ge), Group IV-IV compound semiconductors, such as silicon germanium (SiGe) or silicon carbide (SiC), or Group III-V compound semiconductors, such as gallium arsenide (GaAs), indium arsenide (InAs), or indium phosphide (InP).

The substrate 101 may be based on a Si-bulk substrate. Furthermore, the substrate 101 may be based on a silicon-on-insulator (SOI) substrate, or a germanium-on-insulator (GeOI) substrate. The substrate 101 is not limited to a Si-bulk substrate or an SOI or GeOI substrate, but may be based on an epitaxial wafer, a polished wafer, or a thermal annealed wafer. The substrate 101 may include a conductive area, for example, a well doped with impurities, or various structures doped with impurities. Furthermore, the substrate 101 may form a P-type substrate or an N-type substrate according to the type of doped impurity ions. A peripheral circuit and a wiring layer connected to the peripheral circuit may be arranged in a partial area of the substrate 101.

A peripheral circuit area PCA may be arranged in a structure buried under the substrate 101. As such, a structure in which the peripheral circuit area PCA is arranged under the memory cell region MCR is referred to as a cell-on-peri (COP) structure. For example, the 3D DRAM 10 may have a COP structure. In some embodiments, the peripheral circuit area PCA may be separately formed on a second wafer different from a first wafer on which the memory cell region MCR is formed, and as the first wafer and the second wafer are combined though a wafer bonding process, a COP structure may be implemented. The structure of the 3D DRAM 10 is not limited to the COP structure. For example, the 3D DRAM 10 may have a structure in which the peripheral circuit area PCA is arranged at a position apart in a side direction from the memory cell region MCR. A base insulating layer 105 may be arranged on the substrate 101.

The common word line 110 may include a metal material. For example, the common word line 110 may include at least one material selected from among Cu, a Cu alloy, such as CuSn, CuMg, CuNi, CuZn, CuPd, CuAu, CuRe, or CuW, W, a W alloy, Ni, Ru, and Co. However, the material of the common word line 110 is not limited to the materials described above.

The semiconductor layer 120 may have a shape surrounding a part of the common word line 110. For example, the semiconductor layer 120 may have a shape surround three outer surfaces of the first part 110A of the common word line 110. Accordingly, as illustrated in FIG. 2C, the cross-section of the semiconductor layer 120 may have a shape of “U”. The semiconductor layer 120 may surround a part of the common word line 110, as illustrated in FIG. 2A. As illustrated in FIG. 2C, a gate insulating layer 112 may be provided between the semiconductor layer 120 and the common word line 110. The cross-section of the gate insulating layer 112 may also have a shape of “U”.

As may be seen in FIGS. 2A and 2B, in the second horizontal direction, both end sides of the semiconductor layer 120 may correspond to source/drain regions S/D, and the center portion of the semiconductor layer 120 may correspond to a channel region CH. Accordingly, the channel region CH of the semiconductor layer 120 may extend in the second horizontal direction.

The semiconductor layer 120 may include an undoped semiconductor material or a doped semiconductor material. In some embodiments, the semiconductor layer 120 may include general semiconductors, such as single crystal Si, poly-Si, SiGe, or SiC. In some embodiments, the semiconductor layer 120 may include 2D semiconductors including transition metal dichalcogenides (TMDs), such as CuS₂, CuSe₂, WSe₂, MoS₂, MoSe₂, or WS₂, hexagonal boron nitride (h-BN), graphene, carbon nanotube (CNT), or a combination thereof. In some embodiments, the semiconductor layer 120 may include amorphous metal oxide semiconductor, polycrystalline metal oxide semiconductor, or a combination thereof. For example, metal oxide semiconductor may include at least one of In—Zn based oxide (IZO), Zn—Sn based oxide (ZTO), In—Ga based oxide (IGO), Y—Zn based oxide (YZO), and In—Ga—Zn based oxide (IGZO). However, the material of the semiconductor layer 120 is not limited to the materials described above.

The bit line 130 may be in contact with the semiconductor layer 120 while extending in a direction perpendicular to the upper surface of the substrate 101. The bit line 130 may be alternately arranged with the capacitor 140 in the second horizontal direction. In detail, assuming that a portion of the common word line 110 surrounded by the first semiconductor layer 120-1 is a first word line 110-1 and a portion of the common word line 110 surrounded by the second semiconductor layer 120-2 is a second word line 110-2, the first bit line 130-1 may be alternately arranged with the first capacitor 140-1 in the second horizontal direction while contacting the first semiconductor layer 120-1 surrounding the first word line 110-1. Furthermore, the second bit line 130-2 may be alternately arranged with the second capacitor 140-2 in the second horizontal direction while contacting the second semiconductor layer 120-2 surrounding the second word line 110-2. Furthermore, the first bit line 130-1 and the second bit line 130-2 may be arranged in a zigzag shape in the second horizontal direction between the first word line 110-1 and the second word line 110-2.

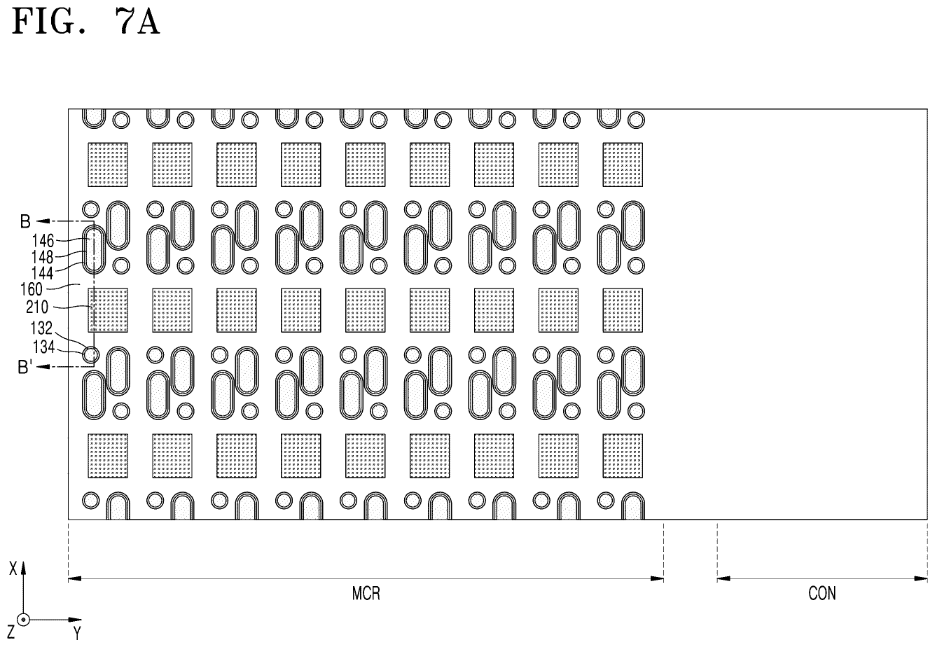

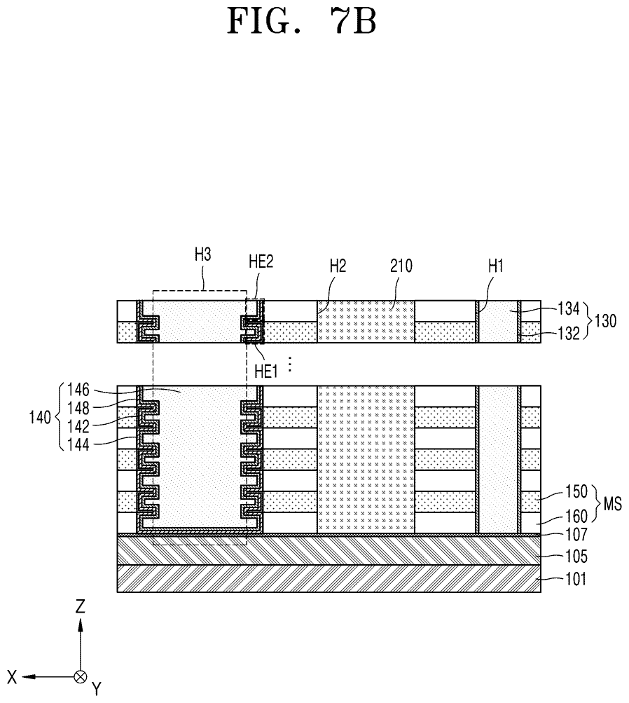

The bit line 130 may have a column shape in the vertical direction, for example, a cylindrical shape. However, the column shape of the bit line 130 is not limited to a cylindrical shape. The bit line 130, as illustrated in FIG. 7B, may include a first barrier metal layer 132 forming the outer surface of the bit line 130 and an electrode metal layer 134 forming the center portion of the bit line 130. The first barrier metal layer 132 may include at least one material selected from among Ti, TiN, Ta, TaN, Ru, Co, Mn, WN, Ni, and NiB. However, the material of the first barrier metal layer 132 is not limited to the materials described above. In some embodiments, the first barrier metal layer 132 may be formed in a multilayer. The electrode metal layer 134 may include a metal material. For example, the electrode metal layer 134 may include at least one material selected from among Cu, a Cu alloy, such as CuSn, CuMg, CuNi, CuZn, CuPd, CuAu, CuRe, or CuW, W, a W alloy, Ni, Ru, and Co. However, the material of the electrode metal layer 134 is not limited to the materials described above.

The capacitor 140 may be in contact with the semiconductor layer 120 while extending in a direction perpendicular to the upper surface of the substrate 101. The capacitor 140 may be alternately arranged with the bit line 130 in the second horizontal direction. The description for the bit line 130 presented above may be applied to the alternate arrangement between the capacitor 140 and the bit line 130. The first capacitor 140-1 and the second capacitor 140-2 may be arranged in a zigzag shape between the first word line 110-1 and the second word line 110-2 in the X direction.

The capacitor 140 may have a column shape extending in the vertical direction, for example, an oval column shape. However, the column shape of the capacitor 140 is not limited to the oval column shape. The capacitor 140 may include a first electrode 142, a dielectric film 144, and a second electrode 146 that are sequentially arranged in the horizontal direction from the outer surface of the capacitor 140 toward the center of the capacitor 140. In detail, at the vertical level at which the common word line 110 is arranged, the capacitor 140 may include the first electrode 142, the dielectric film 144, and the second electrode 146 that are sequentially arranged in the horizontal direction from the outer surface of the capacitor 140 toward the center of the capacitor 140. Furthermore, at the vertical level at which a second mold layer 160 between two common word lines 110 that are adjacent in the vertical direction is arranged, the capacitor 140 may include the dielectric film 144 and the second electrode 146 that are sequentially arranged in the horizontal direction from the outer surface of the capacitor 140 toward the center of the capacitor 140.

As illustrated in FIG. 2A, the first electrodes 142 may each have a ring shape in a plan view, and may be stacked spaced apart from each other in the vertical direction. As illustrated in FIG. 2C, the vertical cross-section of the first electrode 142 may have a shape of “U.” The second electrode 146 may have a column shape having a ring-shaped recess formed in the outer surface thereof. The first electrode 142 may be inserted in a recess portion of the second electrode 146. The dielectric film 144 may surround the outer surface of the second electrode 146, and may be provided in the recess portion between the first electrode 142 and the second electrode 146. Accordingly, the first electrode 142 and the dielectric film 144 of the capacitor 140 may be alternately exposed to the outside in the vertical direction. In other words, at the height corresponding to the common word line 110 in the vertical direction, the first electrode 142 of the capacitor 140 may be exposed to the outside and in contact with the semiconductor layer 120. Furthermore, at the height between two common word lines 110 adjacent to each other in the vertical direction, the dielectric film 144 of the capacitor 140 may be exposed to the outside and in contact with the second mold layer 160.

As illustrated in FIG. 2A, the outer surface of the first electrode 142 and the outer surface of the dielectric film 144, both exposed to the outside, may be substantially coplanar with each other. Here, being substantially coplanar may include not only being completely coplanar but also being approximately coplanar within a tolerance caused by, for example, a process error or a measurement error recognizable by one of ordinary skill in the art. Furthermore, being substantially coplanar may include not only a case in which elements are completely on the same plane, but also a case in which the elements are approximately on the same plane within a tolerance caused by, for example, a process error or a measurement error recognizable by one of ordinary skill in the art. In other words, the outer surface of the first electrode 142 exposed to the outside and the outer surface of the dielectric film 144 exposed to the outside may be continuously connected in one planar form without bending in the vertical direction. As the first electrodes 142 having a ring shape are arranged in the vertical direction in a stacked structure, the structure of the capacitor 140 of the 3D DRAM 10 may be referred to as a stack ring structure. For the stack ring structure, like a general one cylinder stack (OCS) structure, both lateral surfaces of the first electrode 142 are used as a capacitor, and thus in some embodiments, the stack ring structure may be referred to as an OCS structure.

In some embodiments, a second barrier metal layer 148 may be provided between the dielectric film 144 and the second electrode 146. The second barrier metal layer 148 may have a similar structure to the dielectric film 144. The second barrier metal layer 148 may be formed together with the first barrier metal layer 132. Furthermore, the second electrode 146 may be formed together with the electrode metal layer 134. The second electrodes 146 of the capacitors 140 may be commonly connected to a plate electrode PP at an upper end portion thereof in the vertical direction.

The first electrode 142 may include substantially the same metal material as the first barrier metal layer 132. Accordingly, the first electrode 142 may include at least one material selected from among Ti, TiN, Ta, TaN, Ru, Co, Mn, WN, Ni, and NiB. However, the material of the first electrode 142 is not limited to the materials described above. For example, the first electrode 142 may include a similar metal material to the second electrode 146.

The dielectric film 144 may include a high-k dielectric film, a ferroelectric film, or an anti-ferroelectric film. The dielectric film 144 may include a hafnium (Hf)-based or zirconium (Zr)-based material, for example, hafnium oxide (HfO₂), hafnium silicon oxide (HfSiO), hafnium silicon oxynitride (HfSiON), hafnium oxynitride (HfON), hafnium aluminum oxide (HfAlO), hafnium lanthanum oxide (HfLaO), zirconium oxide (ZrO2), or zirconium silicon oxide (ZrSiO). The material of the dielectric film 144 is not limited to the Hf-based or Zr-based material, and the dielectric film 144 may include other dielectric materials, for example, lanthanum oxide (La2O₃), lanthanum aluminum oxide (LaAlO₃), tantalum oxide (Ta₂O₅), titanium oxide (TiO₂), strontium titanium oxide (SrTiO₃), yttrium oxide (Y₂O₃), aluminum oxide (Al₂O₃), red scandium tantalum oxide (PbSc_{0.5}Ta_{0.5}O₃), or lead zinc niobate (PbZnNbO₃). The dielectric film 144 may be formed in a single film or a multi-film.

The second electrode 146 may include a metal material. For example, the second electrode 146 may include at least one material selected from among Cu, a Cu alloy, such as CuSn, CuMg, CuNi, CuZn, CuPd, CuAu, CuRe, or CuW, W, a W alloy, Ni, Ru, and Co. However, the material of the second electrode 146 is not limited to the materials described above.

The second barrier metal layer 148 may include substantially the same metal material as the first barrier metal layer 132. Accordingly, the second barrier metal layer 148 may include at least one material selected from among Ti, TiN, Ta, TaN, Ru, Co, Mn, WN, Ni, and NiB. However, the material of the second barrier metal layer 148 is not limited to the materials described above.

As described above with reference to FIGS. 2A to 2C, the 3D DRAM 10 according to an embodiment may include a DRAM cell having a 1TR-1CAP structure in which one capacitor 140 is connected to one transistor. Furthermore, the 3D DRAM 10, which adopts the structure of the bit line 130 that extends in the vertical direction, may be advantageous in the sensing margin. Furthermore, the 3D DRAM 10, which includes the capacitors 140 arranged in a stack ring structure, may have an increased storage capacity compared with a general column structure. Furthermore, the following merits may be induced in the manufacturing process of the 3D DRAM 10. First, the semiconductor layer 120 is formed through a deposition process and has a structure of surrounding the surface of the common word line 110, and thus the process difficulty of a channel of the semiconductor layer 120 may be low. Second, the common word line 110 may be formed through the forming of a thin side surface recess, and thus the process difficulty of the common word line 110 may be low. Third, the capacitor 140 having the stack ring structure may be formed through the forming of the thin side surface recess, and thus, the process difficulty of the capacitor 140 may be low. For reference, the forming of the thin side surface recess may mean that a corresponding recess portion may be filled with low step coverage process capability so as to be concluded to low process difficulty with respect to a corresponding component.

FIGS. 3A and 3B are a perspective view and a cross-sectional view, respectively, of the connection region CON of the 3D DRAM 10 according to an embodiment. FIG. 3A is a perspective view schematically illustrating only the step region SDP and word-line contact plugs of the connection region CON, and FIG. 3B is a vertical cross-sectional view schematically illustrating a structure in which fourth, eighth, twelfth, and sixteenth word-line contact plugs 180-4, 180-8, 180-12, and 180-16 are in contact with fourth, eighth, twelfth, and sixteenth word line pads 113-4, 113-8, 113-12, and 113-16, respectively. Although FIGS. 3A and 3B illustrate only four word-line contact plugs 180-4, 180-8, 180-12, and 180-16, this is merely for convenience of explanation. Sixteen word-line contact plugs in contact with word line pads 113-1, 113-2, . . . , and 113-16 may be arranged in the connection region CON. Although the connection region CON may include the step region 150SDP including a large number of layers, in the description, for convenience of explanation, the step region 150SDP including a total of sixteen layers is described as an example.

In the descriptions below, the ordinal number used before each of the word-line contact plug 180, the word line pad 113, and the connection mold layer 150CO may refer to the layer number or connection layer number of a corresponding component. For example, based on the vertical direction, the first word line pad 113-1 may be disposed on the 1st layer, and the twelfth word line pad 113-12 may be disposed on the 12th layer. Furthermore, a third connection mold layer 150CO-3 may be disposed on the 3rd layer, and a thirteenth connection mold layer 150CO-13 may be disposed on the 13th layer. Furthermore, based on the vertical direction, the twelfth word-line contact plug 180-12 may be connected to the twelfth word line pad 113-12 on the 12th layer, and the eighth word-line contact plug 180-8 may be connected to the eighth word line pad 113-8 disposed on the 8th layer.

The connection region CON of the 3D DRAM 10 may include the step region 150SDP. The step region 150SDP may include connection mold layers 150CO-1, 150CO-2, . . . , and 150CO-16 and the second mold layers 160 that are alternately arranged in the vertical direction, and also include the word line pads 113-1, 113-2, . . . , and 113-16. In some embodiments, as the vertical level decreases, the width of the second mold layers 160 in the first horizontal direction and the width of each of the connection mold layers 150CO-1, 150CO-2, . . . , and 150CO-16 in the first horizontal direction may increase in a staircase manner. For example, the width of each of the sixteenth, fifteenth, fourteenth, and thirteenth connection mold layers 150CO-16, 150CO-15, 150CO-14, and 150CO-13 in the first horizontal direction may sequentially increase from the sixteenth connection mold layer 150CO-16 to the thirteenth connection mold layer 150CO-13. Furthermore, the width of each of the twelfth, eleventh, tenth, and ninth connection mold layers 150CO-12, 150CO-11, 150CO-10, and 150CO-9 in the first horizontal direction, the width of each of the eighth, seventh, sixth, and fifth connection mold layers 150CO-8, 150CO-7, 150CO-6, and 150CO-5 in the first horizontal direction, and the width of each of the fourth, third, second, and first connection mold layers 150CO-4, 150CO-3, 150CO-2, and 150CO-1 in the first horizontal direction may sequentially increase as the layer number decreases.

In some embodiments, whenever the vertical level decreases by a particular vertical height, the width of the second mold layers 160 in the second horizontal direction and the width of each of the connection mold layers 150CO-1, 150CO-2, . . . , and 150CO-16 in the second horizontal direction may increase. For example, whenever the vertical level decreases by four layers, the width of each of the connection mold layer 150CO and the second mold layer 160 in the second horizontal direction may increase. In detail, the sixteenth, the width of each of the sixteenth, fifteenth, fourteenth, and thirteenth connection mold layers 150CO-16, 150CO-15, 150CO-14, and 150CO-13 in the second horizontal direction may be less than the width of each of the twelfth, eleventh, tenth, and ninth connection mold layers 150CO-12, 150CO-11, 150CO-10, and 150CO-9 in the second horizontal direction, and the width of each of the twelfth, eleventh, tenth, and ninth connection mold layers 150CO-12, 150CO-11, 150CO-10, and 150CO-9 in the second horizontal direction may be less than the width of each of the eighth, seventh, sixth, and fifth connection mold layers 150CO-8, 150CO-7, 150CO-6, and 150CO-5 in the second horizontal direction. Furthermore, the width of each of the eighth, seventh, sixth, and fifth connection mold layers 150CO-8, 150CO-7, 150CO-6, and 150CO-5 in the second horizontal direction may be less than the width of each of the fourth, third, second, and first connection mold layers 150CO-4, 150CO-3, 150CO-2, and 150CO-1 in the second horizontal direction.

In some other embodiments, while the width of each of the connection mold layers 150CO-1, 150CO-2, . . . , and 150CO-16 in the second horizontal direction may increase in a staircase manner as the vertical level decreases, and the width of each of the connection mold layers 150CO-1, 150CO-2, . . . , and 150CO-16 in the first horizontal direction may increase whenever the vertical level decreases by a specific vertical height (e.g., four layers).

Each of the word line pads 113-1, 113-2, . . . , and 113-16 may have a liner shape surrounding the side walls of each of the connection mold layers 150CO-1, 150CO-2, . . . , and 150CO-16, and the outer walls of each of the word line pads 113-1, 113-2, . . . , and 113-16 may form substantially the same plane as the side walls of each of the second mold layers 160 respectively disposed on the connection mold layers 150CO-1, 150CO-2, . . . , and 150CO-16. In a detailed example, the sixteenth word line pad 113-16 may cover the side walls of the sixteenth connection mold layer 150CO-16, and the outer walls of the sixteenth word line pad 113-16 may form substantially the same plane as the side walls of the second mold layer 160 on the sixteenth connection mold layer 150CO-16. In other words, the outer walls of the sixteenth word line pad 113-16 having a liner shape surrounding the side walls of the sixteenth connection mold layer 150CO-16 and the side walls of the second mold layer 160 on the sixteenth connection mold layer 150CO-16 may be continuously connected in one planar form without bending in the vertical direction.

In some embodiments, some of the inner walls of the word line pads 113-1, 113-2, . . . , and 113-16 may be in contact with a horizontal portion of the word-line contact plug 180. The word-line contact plugs 180 may each include a vertical portion and the horizontal portion. The structure of the word-line contact plug 180 is described based on the sixteenth word-line contact plug 180-16 as an example.

The sixteenth word-line contact plug 180-16 may include a vertical portion 180-16v that penetrates the cover insulating layer 190 in the vertical direction and a horizontal portion 180-16h that extends from the vertical portion 180-16v in the horizontal direction. A lower surface 180-16_ls of the sixteenth word-line contact plug 180-16 may be in contact with the second mold layer 160 disposed below the sixteenth connection mold layer 150CO-16. For example, the sixteenth word-line contact plug 180-16 may include a metal material. For example, the sixteenth word-line contact plug 180-16 may include at least one material selected from among Cu, a Cu alloy, such as CuSn, CuMg, CuNi, CuZn, CuPd, CuAu, CuRe, or CuW, W, a W alloy, Ni, Ru, and Co. However, the material of the sixteenth word-line contact plug 180-16 is not limited to the materials described above.

The vertical portion 180-16v of the sixteenth word-line contact plug 180-16 may penetrate the cover insulating layer 190 in the vertical direction. The vertical portion 180-16v may have a tapered shape downwardly from an upper portion. In some embodiments, the vertical portion 180-16v may extend in the vertical direction from the upper surface of the cover insulating layer 190 to the upper surface of the sixteenth connection mold layer 150CO-16. The vertical portion 180-16v may penetrate the second mold layer 160 on the sixteenth connection mold layer 150CO-16 in the vertical direction. Accordingly, the side wall of the vertical portion 180-16v may be covered by the cover insulating layer 190 and the second mold layer 160.

The horizontal portion 180-16h of the sixteenth word-line contact plug 180-16 may extend from the vertical portion 180-16v in the horizontal direction, and penetrate the sixteenth connection mold layer 150CO-16 in the horizontal direction. In some embodiments, the horizontal cross-section of the horizontal portion 180-16h may have a circular shape or an oval shape. The vertical cross-section of the horizontal portion 180-16h may have a bowl shape that is downwardly convex. The side wall of the horizontal portion 180-16h may be in contact with the sixteenth connection mold layer 150CO-16 and the sixteenth word line pad 113-16.

In some embodiments, a first side wall 180-16h_sw1 of the entire side wall of the horizontal portion 180-16h may be covered by the sixteenth connection mold layer 150CO-16. Furthermore, a second side wall 180-16h_sw2 of the entire side wall of the horizontal portion 180-16h, except for the first side wall 180-16h_sw1, may be in contact with the sixteenth word line pad 113-16. The first side wall 180-16h_sw1 of the horizontal portion 180-16h may have a curved surface shape that is downwardly convex, and the second side wall 180-16h_sw2 may have a flat shape that extends in the vertical direction.

Although, in the description presented above, the arrangement structure of only the sixteenth word-line contact plug 180-16, the sixteenth word line pad 113-16, and the sixteenth connection mold layer 150CO-16 are described in detail, each of other word-line contact plugs 180-4, 180-8, and 180-12 may be arranged based on the same arrangement structure as that described above. For example, the other word-line contact plugs 180-4, 180-8, and 180-12 may include vertical portions 180-4v, 180-8v, and 180-12v and horizontal portions 180-4h, 180-8h, and 180-12h, respectively, and may be arranged to contact the corresponding connection mold layers 150CO-4, 150CO-8, and 150CO-12 and the corresponding word line pads 113-4, 113-8, and 113-12, respectively.

As described above, in the connection region CON, the word line pads 113-1, 113-2, . . . , and 113-16 may have a liner shape thinly surrounding the connection mold layers 150CO-1, 150CO-2, . . . , and 150CO-16, respectively. As the word line pads 113-1, 113-2, . . . , and 113-16 have a liner shape, at a specific vertical level of the connection region CON, a proportion occupied by a metal material (e.g., the first word line pad 113-1) may be much smaller than a proportion occupied by an insulator material (e.g., the first connection mold layer 150CO-1). Accordingly, parasitic capacitance between upper/lower word line pads may be much small, and the problems generated due to the parasitic capacitance may be addressed. The description presented above may be merely an example about the step region 150SDP, and the step region 150SDP is not limited to the example described above and may be implemented in various shapes.

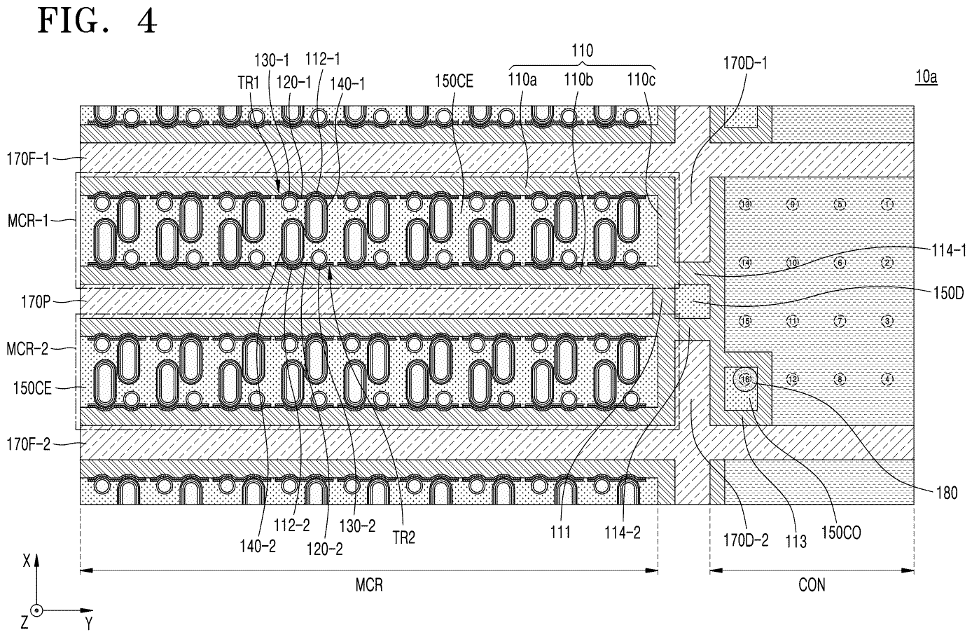

FIG. 4 is a cross-sectional view of a 3D DRAM 10A according to another embodiment. FIG. 4 is a horizontal cross-sectional view of the 3D DRAM 10A cut in the horizontal direction at a vertical level corresponding to the 16th layer of the 3D DRAM 10A in the vertical direction. In the description with reference to FIG. 4, any redundant descriptions presented above are omitted, and the configuration of the 3D DRAM 10A is mainly described. Referring to FIG. 4, the 3D DRAM 10A may include a dummy mold layer 150D, a first region separation insulating layer 170D-1, and a second region separation insulating layer 170D-2.

The dummy mold layer 150D may be a part of the first mold layer 150 arranged between the memory cell region MCR and the connection region CON, of the entire first mold layer 150 (see FIG. 2C). The dummy mold layer 150D may be arranged in the first horizontal direction between the first region separation insulating layer 170D-1 and the second region separation insulating layer 170D-2. The dummy mold layer 150D may be alternately arranged with the second mold layer 160 (see FIG. 2C) in the vertical direction.

The first region separation insulating layer 170D-1 may extend in the first horizontal direction from the first stack separation insulating layer 170F-1. The second region separation insulating layer 170D-2 may extend in the first horizontal direction from the second stack separation insulating layer 170F-2. The first region separation insulating layer 170D-1 and the second region separation insulating layer 170D-2 may be apart from each other in the first horizontal direction.

One side wall in the second horizontal direction of each of the first region separation insulating layer 170D-1 and the second region separation insulating layer 170D-2 may be in contact with the third part 110c of the common word line 110, and an opposite side wall facing the one side wall of each of the first region separation insulating layer 170D-1 and the second region separation insulating layer 170D-2 may be in contact with the word line pad 113.

The word line connection portion 111 may be arranged between the first and second region separation insulating layers 170D-1 and 170D-2 and the partial-separation insulating layer 170P. The word line connection portion 111 may interconnect the common word lines 110 of the two memory cell regions MCR-1 and MCR-2 arranged adjacent to the partial-separation insulating layer 170P. In some embodiments, the word line connection portion 111 may be arranged between the dummy mold layer 150D and the partial-separation insulating layer 170P.

The first pad connection portion 114-1 may be arranged between the first region separation insulating layer 170D-1 and the dummy mold layer 150D in the first horizontal direction, and the second pad connection portion 114-2 may be arranged between the second region separation insulating layer 170D-2 and the dummy mold layer 150D in the first horizontal direction. The first pad connection portion 114-1 may be connected to the common word line 110 of the first memory cell region MCR-1 arranged adjacent to the first region separation insulating layer 170D-1, among the memory cell regions closest to the dummy mold layer 150D. The second pad connection portion 114-2 may be connected to the common word line 110 of the second memory cell region MCR-2 arranged adjacent to the second region separation insulating layer 170D-2, among the memory cell regions closest to the dummy mold layer 150D. In a detailed example, as illustrated in FIG. 4, the first pad connection portion 114-1 may connect the common word line 110 of the first memory cell region MCR-1 to the word line pad 113, and the second pad connection portion 114-2 may connect the common word line 110 of the second memory cell region MCR-2 to the word line pad 113.

In the description with reference to FIG. 4, an embodiment in which the 3D DRAM 10A includes only two memory cell regions MCR-1 and MCR-2 is described, but this is merely an example. The 3D DRAM 10A may include K memory cell regions, where K is a natural number greater than or equal to 3, arranged in the first horizontal direction at certain intervals, and in this case, K−1 partial-separation insulating layers 170P may be alternately arranged among a plurality of memory cell regions.

In some embodiments, “K/2” memory cell regions of K memory cell regions, where K is an even number, may be arranged adjacent to the first region separation insulating layer 170D-1, and the other “K/2” memory cell regions may be arranged adjacent to the second region separation insulating layer 170D-2. Among the K memory cell regions, a common word line of each of two memory cell regions closest to the dummy mold layer 150D may be connected to the word line pad 113 via each of the first and second pad connection portions 114-1 and 114-2.

In some other embodiments, among K memory cell regions, where K is an odd number, “[K/2]” memory cell regions may be arranged adjacent to the first region separation insulating layer 170D-1, and the other “[K/2]” memory cell regions may be arranged adjacent to the second region separation insulating layer 170D-2. In this example, “[ ]” indicates the greatest integer function. The remaining one memory cell regions may be arranged adjacent to the dummy mold layer 150D, and the common word line 110 of the remaining one memory cell region may be connected to the word line pad 113 via the first pad connection portion 114-1 and the second pad connection portion 114-2.

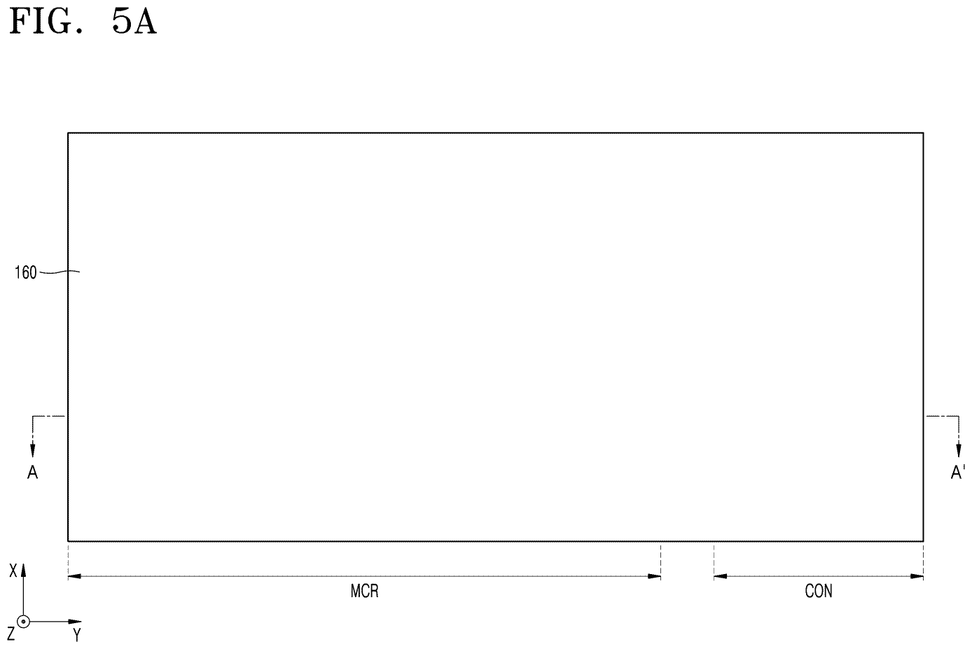

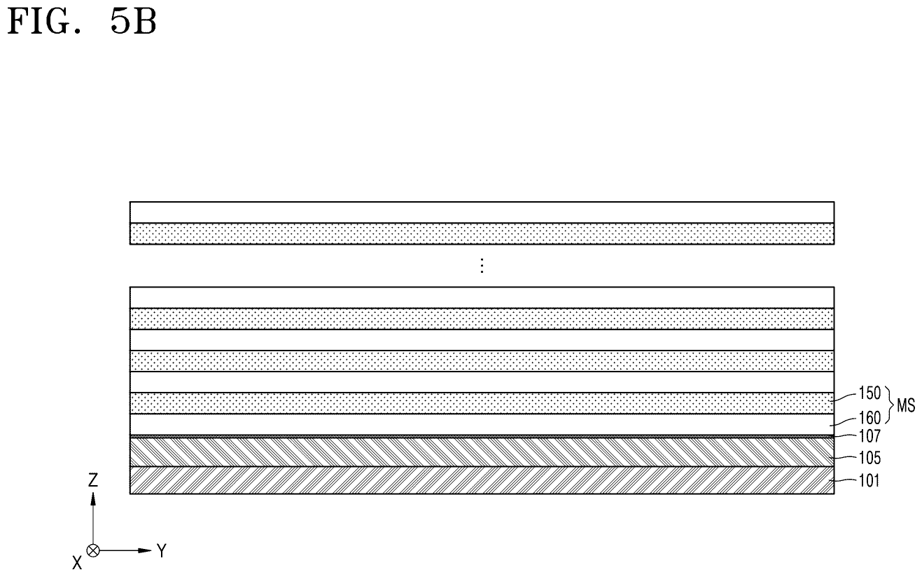

FIGS. 5A, 5B, 6A to 6C, 7A, 7B, 8A, 8B, 9A, 9B, 10A to 10C, 11A, 11B, 12A, 12B, 13, 14, 15A, 15B, 16A, 16B, 17A to 17D, 18, 19A, and 19B are perspective views, plan views and cross-sectional views schematically illustrating processes of a method of manufacturing a 3D DRAM, according to an embodiment.

Referring to FIGS. 5A and 5B, the method of manufacturing a 3D DRAM may include, first, forming the mold structure MS by alternately stacking the first mold layer 150 and the second mold layer 160 over the substrate 101. FIG. 5B is a vertical cross-sectional view of the mold structure MS vertically cut along line A-A′ of FIG. 5A.

Before forming the mold structure MS, the base insulating layer 105 and the etching stop layer 107 may be first formed over the substrate 101. The base insulating layer 105 may include an oxide film, for example, silicon oxide (SiO₂). However, the base insulating layer 105 is not limited to the oxide film. The etching stop layer 107 may include a metal oxide film such as aluminum oxide (AlOx). However, the material of the etching stop layer 107 is not limited to the metal oxide film. In some embodiments, the etching stop layer 107 may be omitted. In the mold structure MS, the second mold layer 160 is disposed at each of the top and bottom portions, and the first mold layer 150 may be alternately arranged with the second mold layer 160 in the Z direction. For example, the first mold layer 150 may include a silicon nitride film, and the second mold layer 160 may include a silicon oxide film. However, the materials of the first mold layer 150 and the second mold layer 160 are not limited to the materials described above. For example, instead of the silicon oxide film and the silicon nitride film, two types of materials having etching selectivity to each other may be used as the first mold layer 150 and the second mold layer 160.

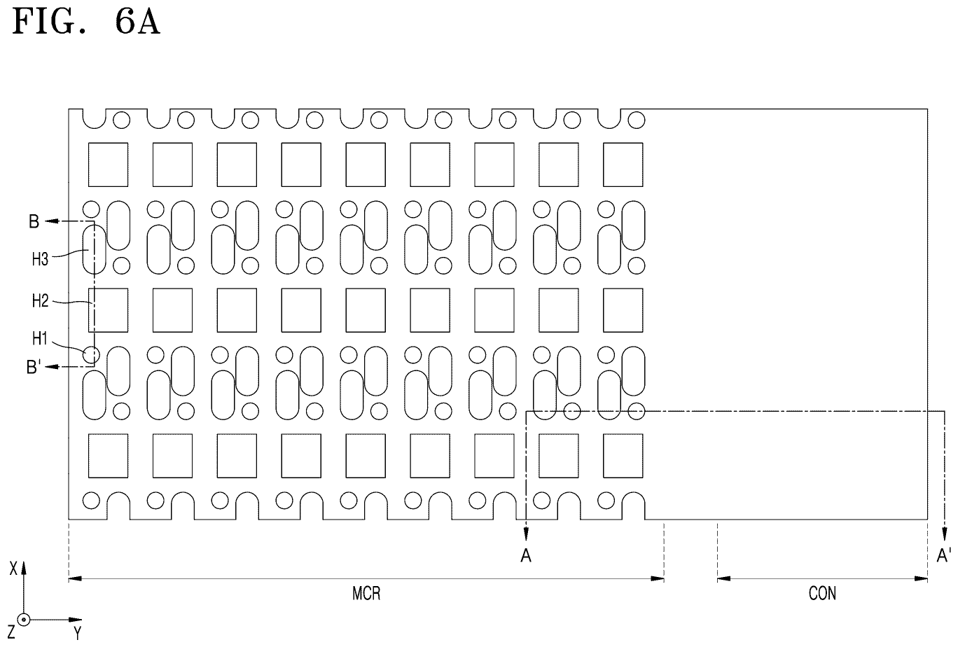

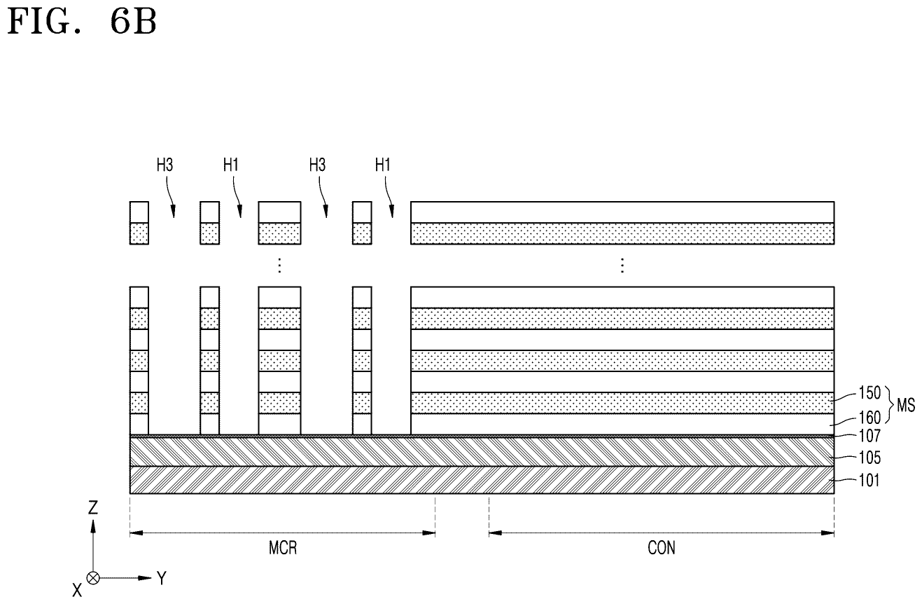

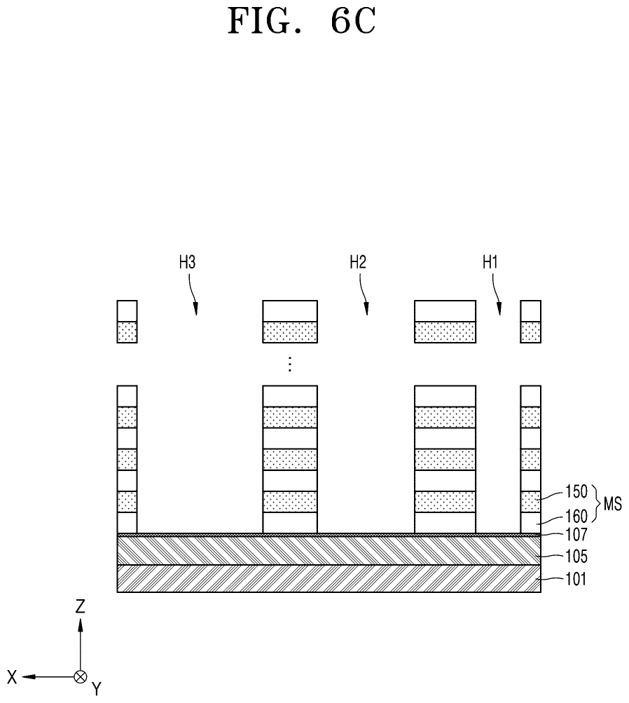

Referring to FIGS. 6A to 6C, the method of manufacturing a 3D DRAM may include, after the forming of the mold structure MS, forming a first through-hole H1, a second through-hole H2, and a third through-hole H3. FIG. 6B is a vertical cross-sectional view of the mold structure MS cut along the line A-A′ of FIG. 6A, and FIG. 6C is a vertical cross-sectional view of the mold structure MS cut along line B-B′ of FIG. 6A.

The forming of the first to third through-holes H1, H2, and H3 may be performed through a photolithography process and an etching process. In this example, the first through-hole H1 may be a through-hole for forming a bit line, the second through-hole H2 may be a through-hole for forming a semiconductor layer and a word line, and the third through-hole H3 may be a through-hole for forming a capacitor. The horizontal cross-section of the first through-hole H1 may have a circular shape, the horizontal cross-section of the second through-hole H2 may have a rectangular shape, and the horizontal cross-section of the third through-hole H3 may have an oval shape extending in the first horizontal direction.

Referring to FIGS. 7A and 7B, the method of manufacturing a 3D DRAM may include forming the capacitor 140 and the bit line 130. FIG. 7B is a vertical cross-sectional view of the mold structure MS cut along line B-B′ of FIG. 7A.

An operation of forming a first horizontal expansion area HE1 may be performed. For the forming of the first horizontal expansion area HE1, first, the first to third through-holes H1, H2, and H3 may each be filled with a first sacrificial layer 210. The first sacrificial layer 210 may include a material with etching selectivity to each of the first mold layer 150 and the second mold layer 160. In some embodiments, the first sacrificial layer 210 may include a material with etching selectivity only to the first mold layer 150. Then, the first sacrificial layer 210 within the third through-hole H3 may be removed so as to open the third through-hole H3. After the opening of the third through-hole H3, by removing a part of the first mold layer 150 from the outer surface of the first mold layer 150 exposed by the third through-hole H3, the first horizontal expansion area HE1 may be formed. The first horizontal expansion area HE1 may be a space expanding from the third through-hole H3 in the horizontal direction.

Then, an operation of forming the first electrode 142 in the first horizontal expansion area HE1 may be performed. The vertical cross-section of the first electrode 142 may have a shape of “U”. Then, an operation of forming a second horizontal expansion area HE2 may be performed. In a detailed example, by removing a part of the second mold layer 160 from the outer surface of the second mold layer 160 exposed by the third through-hole H3, the second horizontal expansion area HE2 may be formed. The second horizontal expansion area HE2 may be a space expanding from the third through-hole H3 in the horizontal direction. In this example, both the first horizontal expansion area HE1 and the second horizontal expansion area HE2 are spaces having an oval ring shape in a plan view.

Then, an operation of forming the dielectric film 144 may be performed on the first horizontal expansion area HE1 and the second horizontal expansion area HE2. The dielectric film 144 may be formed on the inner surface of the first electrode 142, the outer surface of the first electrode 142, and the side surface of the second mold layer 160.

Then, an operation of forming the first barrier metal layer 132 and the second barrier metal layer 148 may be performed. For the forming of the first barrier metal layer 132, first, by removing the first sacrificial layer 210 of the first through-hole H1, the first through-hole H1 may be opened. Next, the first barrier metal layer 132 may be formed within the first through-hole H1, and the second barrier metal layer 148 may be formed within the third through-hole H3, the first horizontal expansion area HE1, and the second horizontal expansion area HE2. The first barrier metal layer 132 may be formed on the side surfaces of the first mold layer 150 and the second mold layer 160 that are exposed by the first through-hole H1, and the second barrier metal layer 148 may be formed on the inner surface of the dielectric film 144. In some embodiments, the forming of the first barrier metal layer 132 and the second barrier metal layer 148 may be omitted.

Then, an operation of forming the electrode metal layer 134 and the second electrode 146 may be performed. The electrode metal layer 134 may be formed on the first barrier metal layer 132, and the second electrode 146 may be formed on the second barrier metal layer 148. In some embodiments, in order to avoid an oxidation issue between the electrode metal layer 134 and the second electrode 146, the first through-hole H1, the third through-hole H3, the first horizontal expansion area HE1, and the second horizontal expansion area HE2 are first filled with a sacrificial layer, and then, at the final operation, the filled sacrificial layer is removed, and then the electrode metal layer 134 and the second electrode 146 may be formed. Through the processes described above, the capacitor 140 including the first electrode 142, the dielectric film 144, the second electrode 146, and the second barrier metal layer 148 may be formed, and the bit line 130 including the first barrier metal layer 132 and the electrode metal layer 134 may be formed.

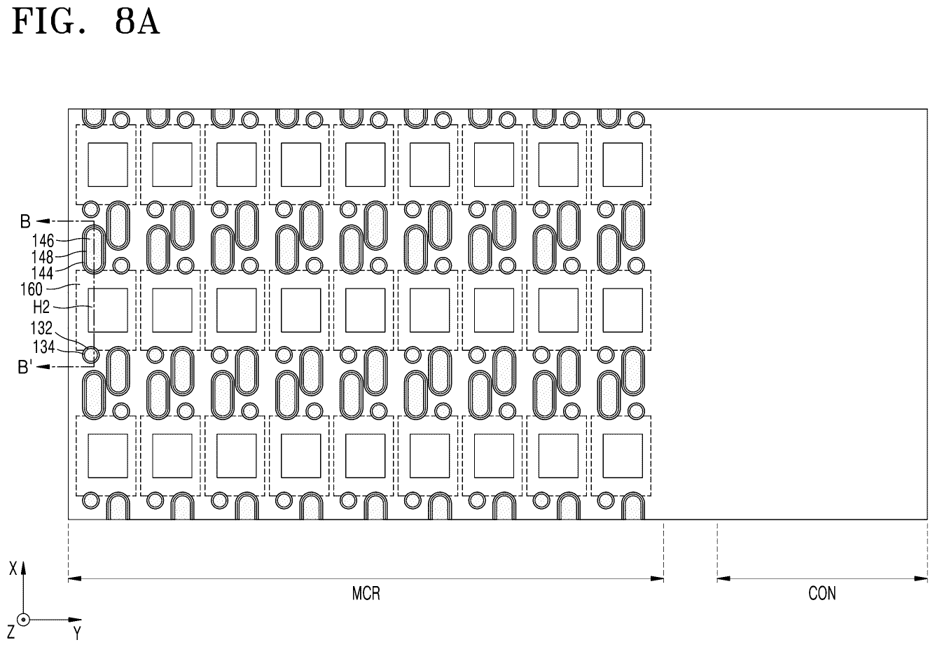

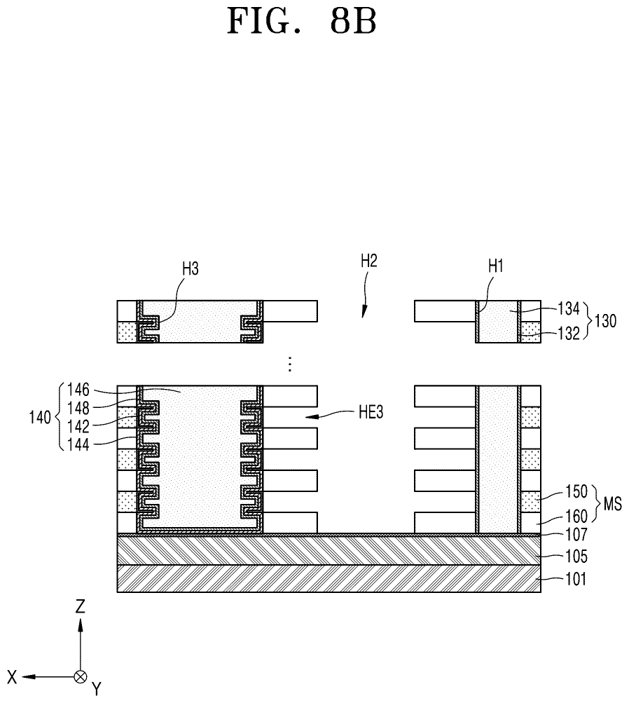

Referring to FIGS. 8A and 8B, the method of manufacturing a 3D DRAM may include an operation of forming a third horizontal expansion area HE3. FIG. 8B is a vertical cross-sectional view of the mold structure MS cut along line B-B′ of FIG. 8A.

In detail, by removing the first sacrificial layer of the second through-hole H2, the second through-hole H2 may be opened. By removing a part of the first mold layer 150 from the outer surface of the first mold layer 150 exposed through the second through-hole H2, the third horizontal expansion area HE3 may be formed. As can be seen through a dashed line surrounding the second through-hole H2 of FIG. 8A, the third horizontal expansion area HE3 may be a space having a quadrangle ring shape, in a plan view. The third horizontal expansion area HE3 may expose the first electrode 142 of the capacitor 140 and the first barrier metal layer 132 of the bit line 130. As illustrated in FIG. 8A, the third horizontal expansion area HE3 surrounding one second through-hole H2 may expose the first barrier metal layer 132 of each of two bit lines 130 spaced apart from each other in the first horizontal direction, and expose the first electrode 142 of each of two capacitors 140 spaced apart from each other in the first horizontal direction.

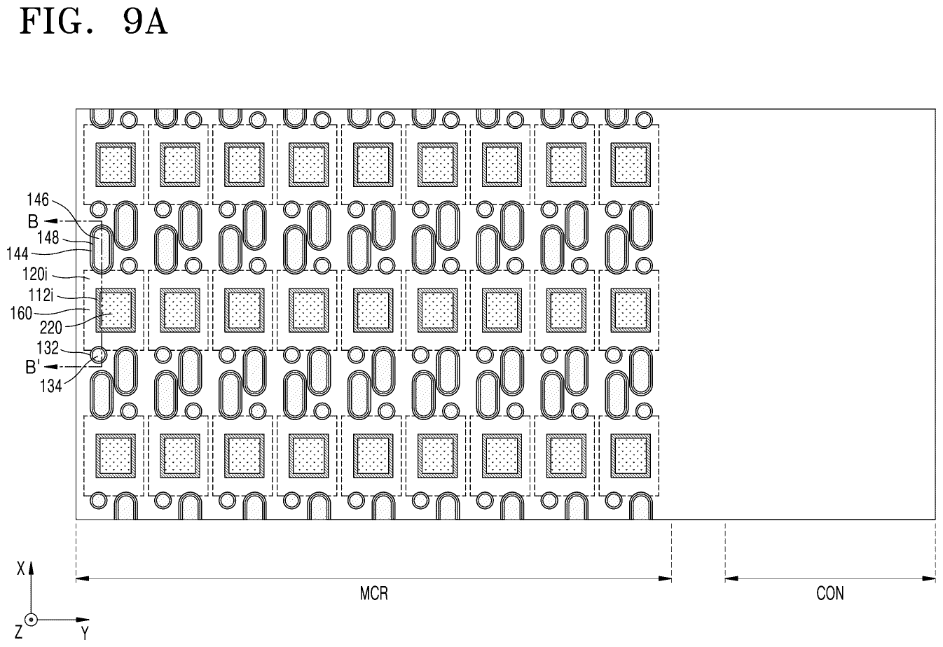

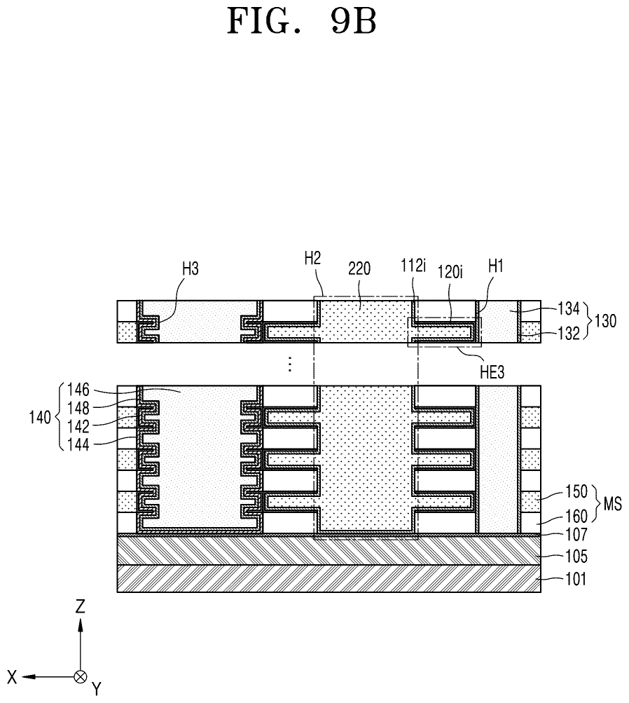

Referring to FIGS. 9A and 9B, the method of manufacturing a 3D DRAM may include an operation of forming an initial semiconductor layer 120i, an initial gate insulating layer 112i, and a second sacrificial layer 220. FIG. 9B is a vertical cross-sectional view of the mold structure MS cut along line B-B′ of FIG. 9A.

First, the initial semiconductor layer 120i may be formed on the third horizontal expansion area HE3. The initial semiconductor layer 120i may have a rectangular ring shape in a plan view, and the vertical cross-section of the initial semiconductor layer 120i may have a shape of “U”. Then, the initial gate insulating layer 112i surrounding the inner surface of the initial semiconductor layer 120i may be formed. The initial gate insulating layer 112i may have a cylindrical shape extending in the vertical direction and have a structure protruding outwardly in the third horizontal expansion area HE3. Furthermore, the initial gate insulating layer 112i may have a rectangular ring shape in a plan view.

Next, the second through-hole H2 and the third horizontal expansion area HE3 may be filled with the second sacrificial layer 220. The second sacrificial layer 220 may have a rectangular column shape and have a structure protruding toward the third horizontal expansion area HE3 in the horizontal direction. In some embodiments, the second sacrificial layer 220 may include a material with etching selectivity to each of the first mold layer 150 and the second mold layer 160.

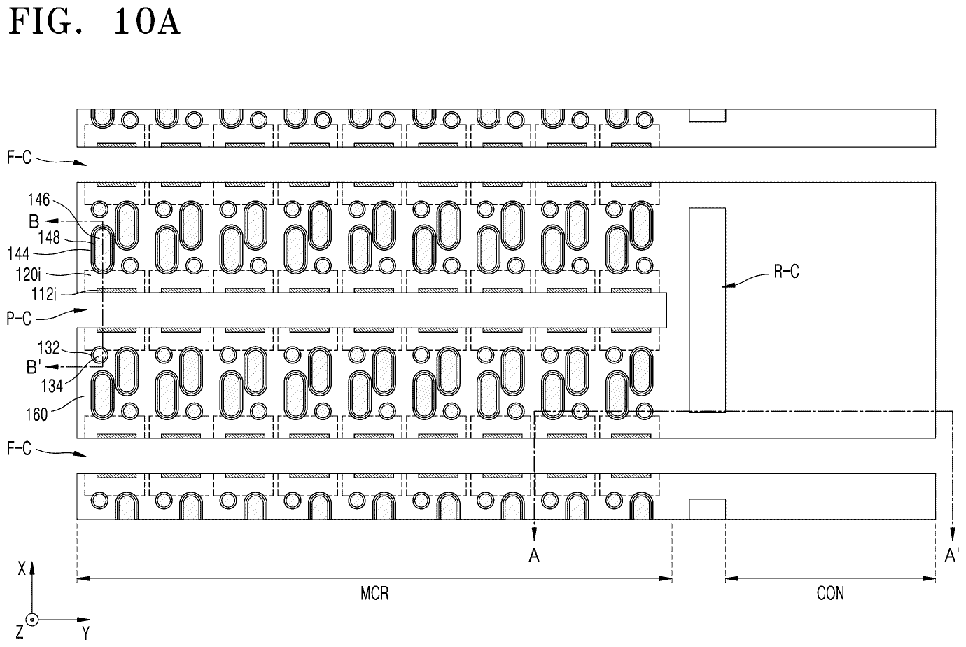

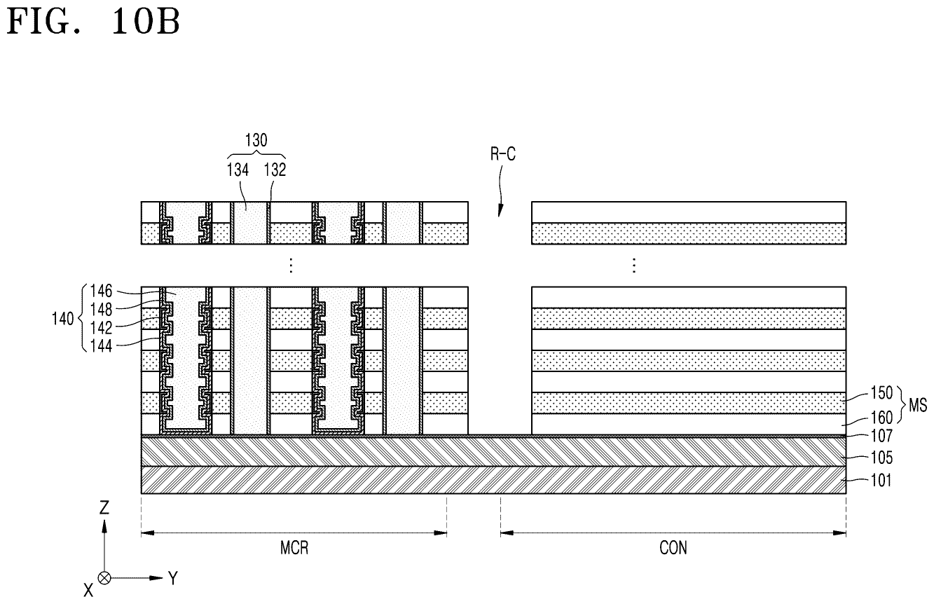

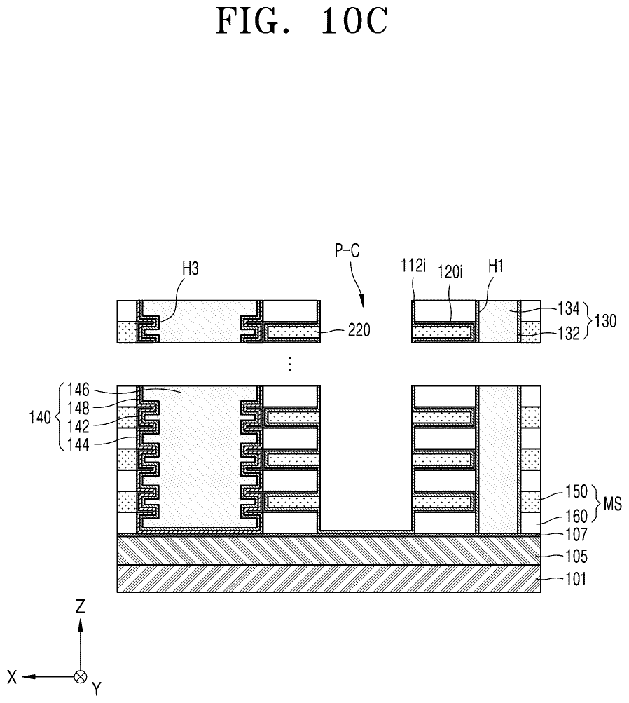

Referring to FIGS. 10A to 10C, the method of manufacturing a 3D DRAM may include an operation of forming a full line-cut F-C, a partial line-cut P-C, and a region line-cut R-C. FIG. 10B is a vertical cross-sectional view of the mold structure MS cut along A-A′ of FIG. 10A, and FIG. 10C is a vertical cross-sectional view of the mold structure MS cut along B-B′ of FIG. 10A.

The full line-cut F-C, the partial line-cut P-C, and the region line-cut R-C may penetrate the mold structure MS in the vertical direction and expose the etching stop layer 107. The full line-cut F-C may extend lengthwise in the second horizontal direction, and the partial line-cut P-C may extend lengthwise in the second horizontal direction between two full line-cuts F-C. The width of the partial line-cut P-C in the second horizontal direction may be less than the width of the full line-cut F-C in the second horizontal direction. The region line-cut R-C may extend lengthwise in the first horizontal direction between two full line-cuts F-C. The region line-cut R-C may be arranged between the memory cell region MCR and the connection region CON.

The full line-cut F-C and the partial line-cut P-C may be formed in a structure to connect the second through-holes H2 to each other in the second horizontal direction. The full line-cut F-C and the partial line-cut P-C may expose the initial gate insulating layer 112i and the second sacrificial layer 220. The region line-cut R-C may expose the first mold layer 150 and the second mold layer 160. The full line-cut F-C, the partial line-cut P-C, and the region line-cut R-C may be formed through a photolithography process and an etching process.

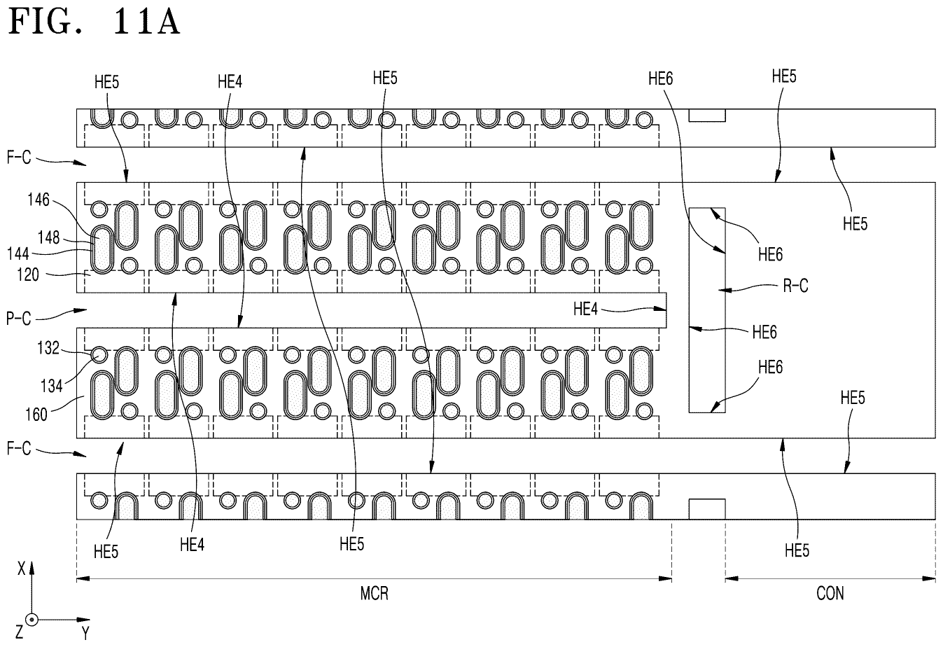

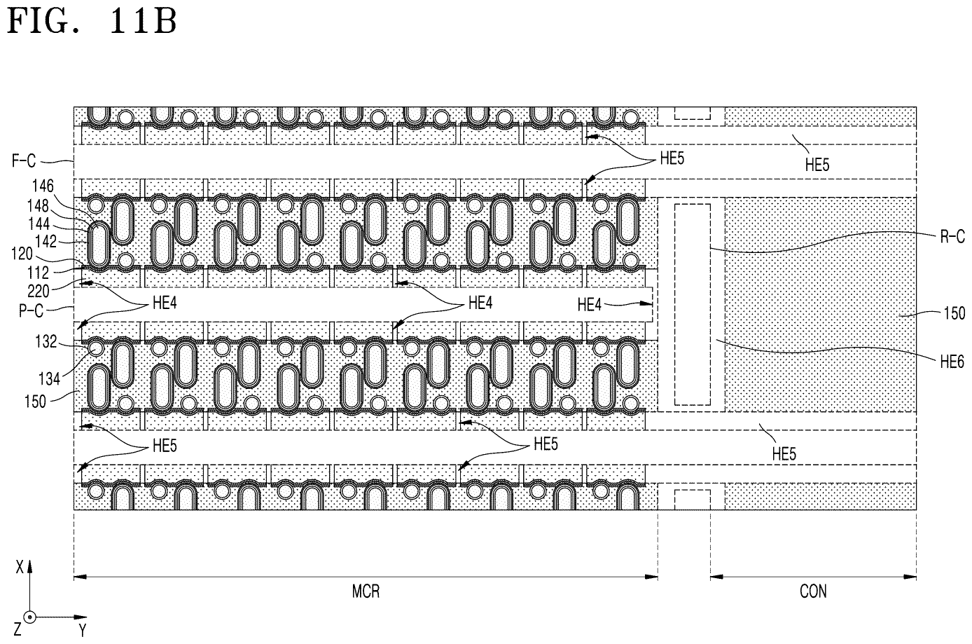

Referring to FIGS. 11A and 11B, the method of manufacturing a 3D DRAM may include an operation of forming a fourth horizontal expansion area HE4, a fifth horizontal expansion area HE5, and a sixth horizontal expansion area HE6. FIG. 11B is a horizontal cross-sectional view of the mold structure MS cut in the horizontal direction at a vertical level where the first mold layer 150 is disposed.

The fourth horizontal expansion area HE4 may be a space expanding from the partial line-cut P-C in the horizontal direction. The fourth horizontal expansion area HE4 may laterally surround the partial line-cut P-C. The fourth horizontal expansion area HE4 may be formed by removing a part of the first mold layer 150 from the outer surface of the first mold layer 150 exposed by the partial line-cut P-C. The fourth horizontal expansion area HE4 may include a space positioned between two second sacrificial layers 220 neighboring in the second horizontal direction. Furthermore, the fourth horizontal expansion area HE4 may include a space positioned between the partial line-cut P-C and the region line-cut R-C, in the second horizontal direction.

The fifth horizontal expansion area HE5 may be a space expanding from the full line-cut F-C in the horizontal direction. The fifth horizontal expansion area HE5 may laterally surround the full line-cut F-C. The fifth horizontal expansion area HE5 may be formed by removing a part of the first mold layer 150 from the outer surface of the first mold layer 150 exposed by the full line-cut F-C. The fifth horizontal expansion area HE5 may include a space positioned between two second sacrificial layers 220 neighboring in the second horizontal direction, in the memory cell region MCR. Furthermore, the fifth horizontal expansion area HE5 may include a space positioned between the first mold layer 150 and the full line-cut F-C, in the first horizontal direction, in the connection region CON.

The sixth horizontal expansion area HE6 may be a space expanding from the region line-cut R-C in the horizontal direction. The sixth horizontal expansion area HE6 may laterally surround the region line-cut R-C. The sixth horizontal expansion area HE6 may be formed by removing a part of the first mold layer 150 from the outer surface of the first mold layer 150 exposed by the region line-cut R-C. The sixth horizontal expansion area HE6 may be connected to the fourth horizontal expansion area HE4 and the fifth horizontal expansion area HE5. In detail, both ends in the first horizontal direction of the sixth horizontal expansion area HE6 may be connected to the fifth horizontal expansion area HE5, and one side in the second horizontal direction of the sixth horizontal expansion area HE6 may be connected to the fourth horizontal expansion area HE4. The horizontal cross-section of the sixth horizontal expansion area HE6 may be a space having a rectangular ring shape extending lengthwise in the first horizontal direction.

The fourth horizontal expansion area HE4, the fifth horizontal expansion area HE5, and the sixth horizontal expansion area HE6 may each be formed through a wet etching process on the first mold layer 150 that is exposed by the partial line-cut P-C, the full line-cut F-C, and the region line-cut R-C. In the wet etching process, an etchant may have very high etching reactivity to the first mold layer 150, but have very low etching reactivity to the second mold layer 160 and the second sacrificial layer 220. However, the fourth horizontal expansion area HE4, the fifth horizontal expansion area HE5, and the sixth horizontal expansion area HE6 may each be formed through various types of processes other than the wet etching process.

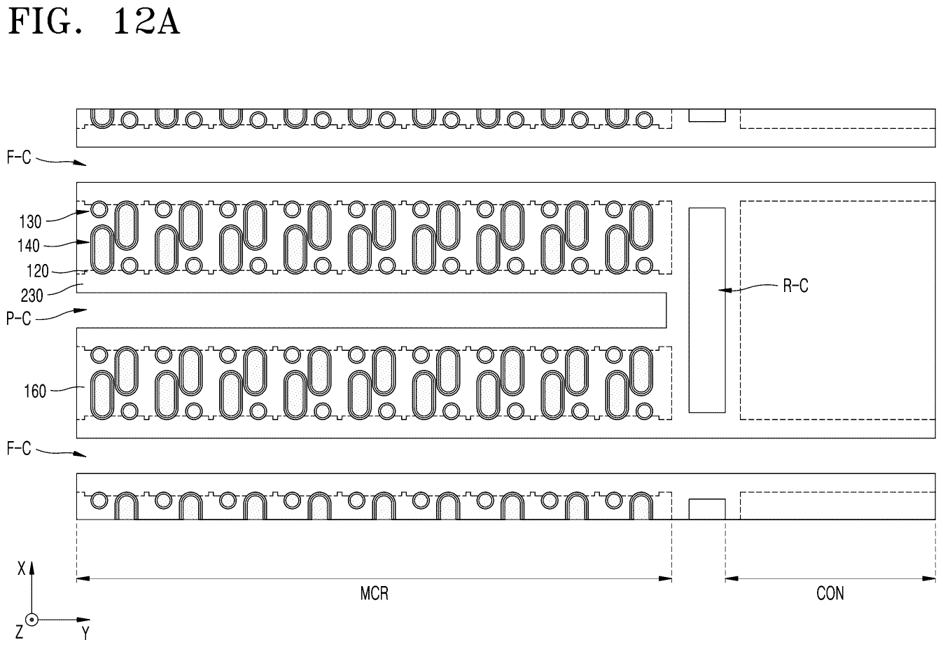

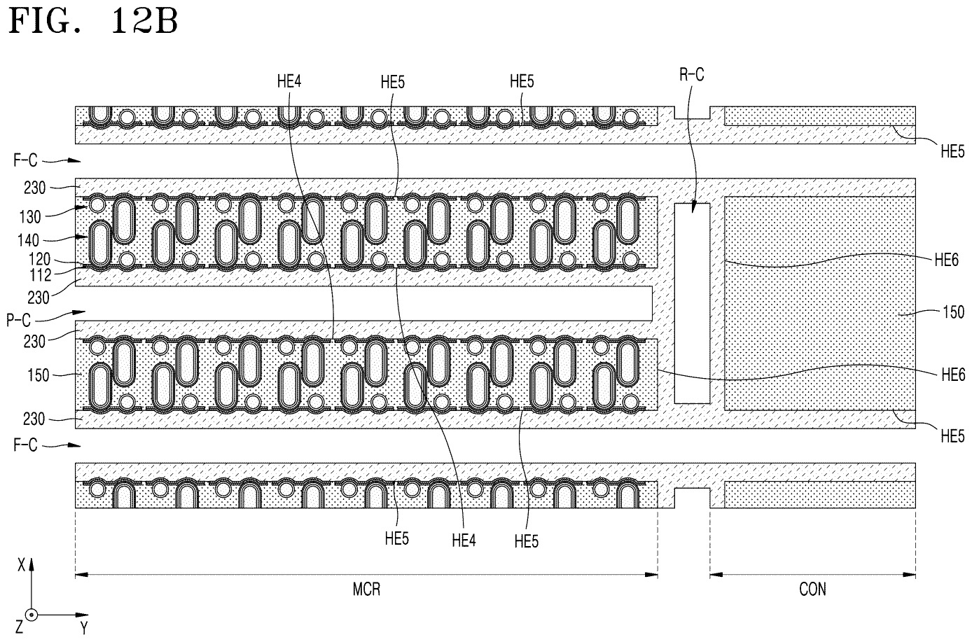

Referring to FIGS. 12A and 12B, the method of manufacturing a 3D DRAM may include an operation of forming a third sacrificial layer 230. FIG. 12B is a horizontal cross-sectional view of the mold structure MS cut in the horizontal direction at a vertical level where the first mold layer 150 is disposed.

First, the second sacrificial layer 220 may be removed. Through the removing of the second sacrificial layer 220, the fourth horizontal expansion area HE4 surrounding the partial line-cut P-C and the fifth horizontal expansion area HE5 surrounding the full line-cut F-C may each be expanded in the horizontal direction.

Then, the third sacrificial layer 230 may be formed to fill the fourth horizontal expansion area HE4, the fifth horizontal expansion area HE5, and the sixth horizontal expansion area HE6. The third sacrificial layer 230 may surround the full line-cut F-C, the region line-cut R-C, and the partial line-cut P-C. Furthermore, the third sacrificial layer 230 may be in contact with the gate insulating layer 112 in the memory cell region MCR and surrounded by the gate insulating layer 112 and the semiconductor layer 120. The third sacrificial layer 230 may cover the side wall of the first mold layer 150 in the memory cell region MCR. The third sacrificial layer 230 may surround the first mold layer 150 in the connection region CON and cover the side wall of the first mold layer 150. The third sacrificial layer 230 may have a thin liner shape in a plan view, which is connected from the memory cell region MCR to the connection region CON. In some embodiments, the third sacrificial layer 230 may include a material with etching selectivity to each of the first mold layer 150 and the second mold layer 160.

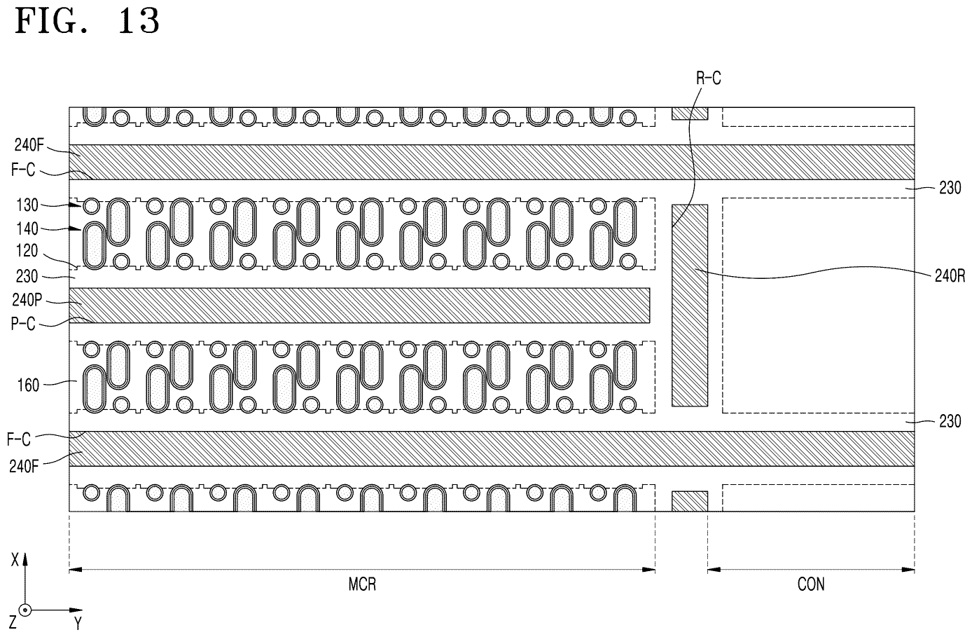

Referring to FIG. 13, the method of manufacturing a 3D DRAM may include an operation of forming fourth sacrificial layers 240F, 240P, and 240R that fill the full line-cut F-C, the partial line-cut P-C, and the region line-cut R-C, respectively. The fourth full sacrificial layer 240F may be a sacrificial layer that fills the full line-cut F-C, the fourth partial sacrificial layer 240P may be a sacrificial layer that fills the partial line-cut P-C, and the fourth region sacrificial layer 240R may be a sacrificial layer that fills the region line-cut R-C.

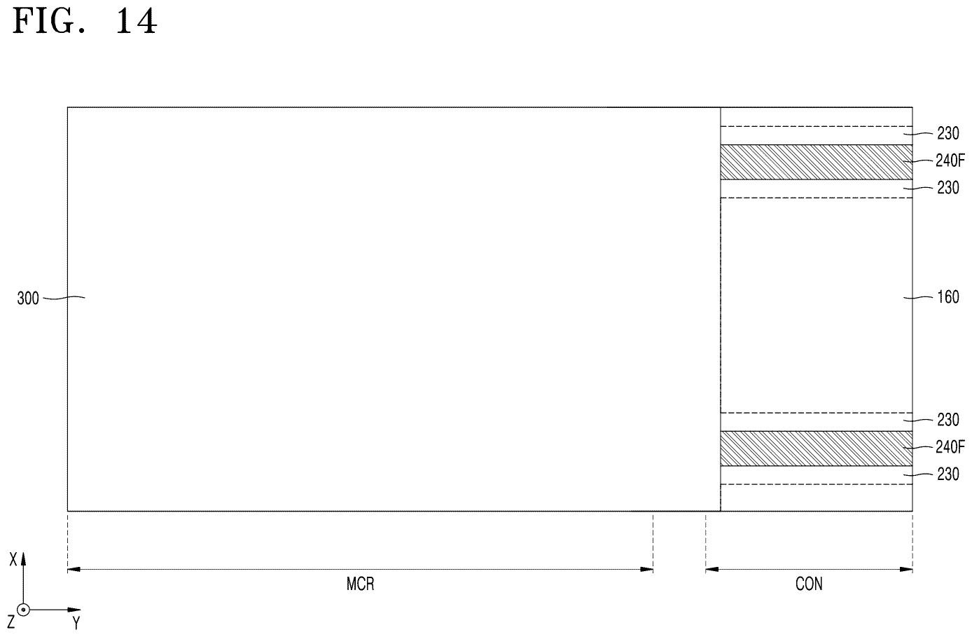

Referring to FIG. 14, the method of manufacturing a 3D DRAM may include an operation of forming a protection layer 300. The protection layer 300 may cover the memory cell region MCR. A part of the connection region CON may be covered by the protection layer 300. The second mold layer 160 and the fourth full sacrificial layer 240F of the connection region CON may not be covered by the protection layer 300 and may be exposed upward.

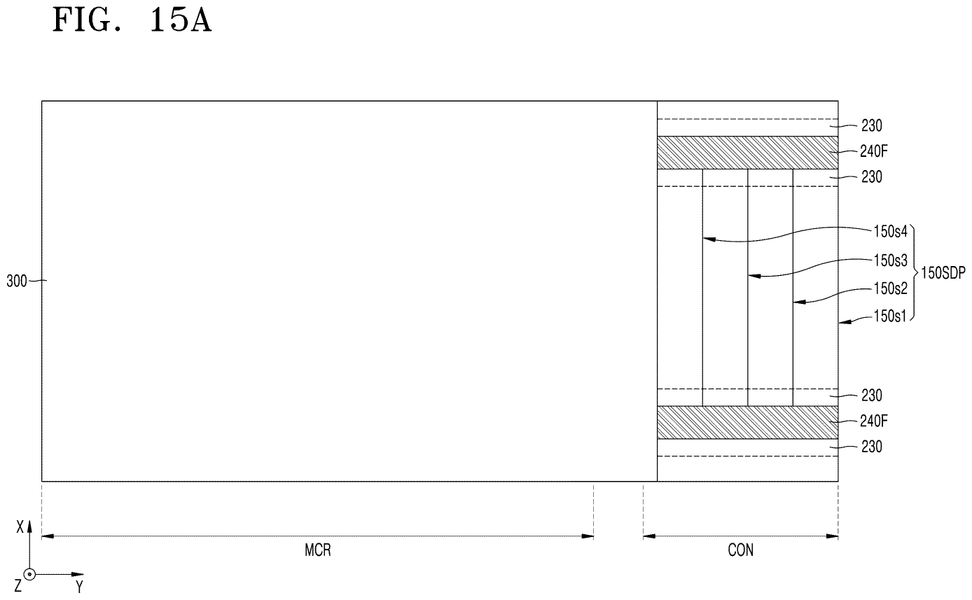

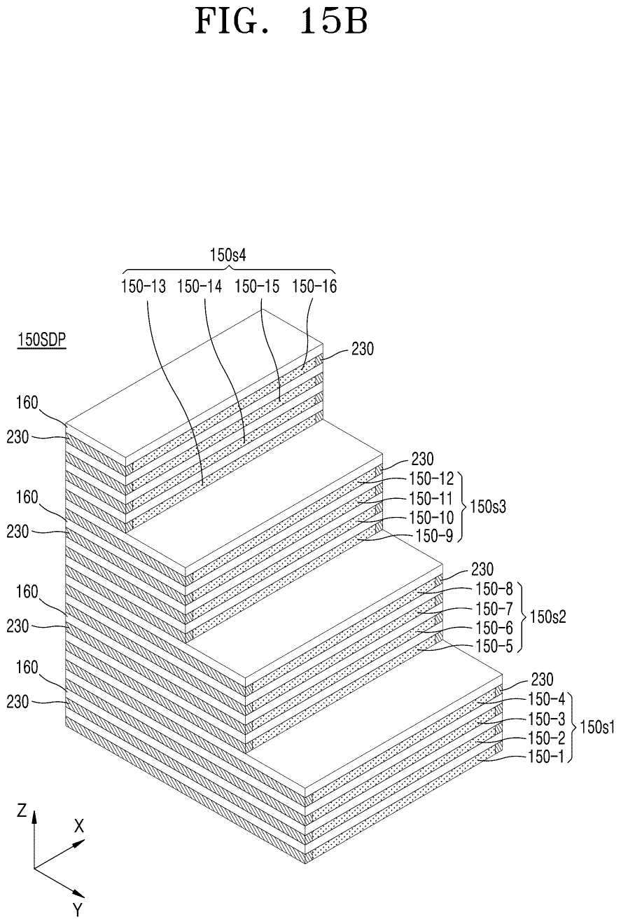

Referring to FIGS. 15A and 15B, the method of manufacturing a 3D DRAM may include an operation of forming the step region 150SDP in the second horizontal direction. FIG. 15B is a perspective view of the step region 150SDP of FIG. 15A.

The step region 150SDP may be formed by performing an etching process of removing the first mold layer 150 and the second mold layer 160 in the vertical direction from the upper surface of the second mold layer 160 that is not covered by the protection layer 300. In the etching process, the horizontal area of an etch mask pattern (e.g., a photoresist pattern) may be gradually reduced in the second horizontal direction.

In a detailed example, in a first etching process, the etch mask pattern may open only a first step region 150s1 of the entire area of the step region 150SDP. In a second etching process after the first etching process, the horizontal area of the etch mask pattern may be reduced through a trim process, and the reduced etch mask pattern may open the first step region 150s1 and a second step region 150s2. As described above, as the etching process progresses, the horizontal area of the etch mask pattern is gradually reduced through the trim process, thereby forming the first to fourth step regions 150s1, 150s2, 150s3, and 150s4 may be formed.

Among the first to fourth step regions 150s1, 150s2, 150s3, and 150s4, the width of the first step region 150s1, having the lowest vertical level, in the second horizontal direction is the greatest, and the width in the second horizontal direction may sequentially increase from the first step region 150s1 to the fourth step region 150s4.

In the step region 150SDP, both side walls in the first horizontal direction of each of the first mold layers 150-1, 150-2,. . . , and 150-16 may be in contact with the third sacrificial layer 230. The third sacrificial layer 230 may thinly surround both side walls in the first horizontal direction of each of the first mold layers 150-1, 150-2, . . . , and 150-16 of the step region 150SDP.

In the description with reference to FIG. 15B, although only the step region 150SDP including the first mold layers 150-1, 150-2, . . . , and 150-16 including 16 layers is described, this is merely an example. The step region 150SDP including the first mold layer 150 less than 16 layers or exceeding 16 layers may be used for forming the step region 150SDP in the second horizontal direction based on the same/similar method as described above.

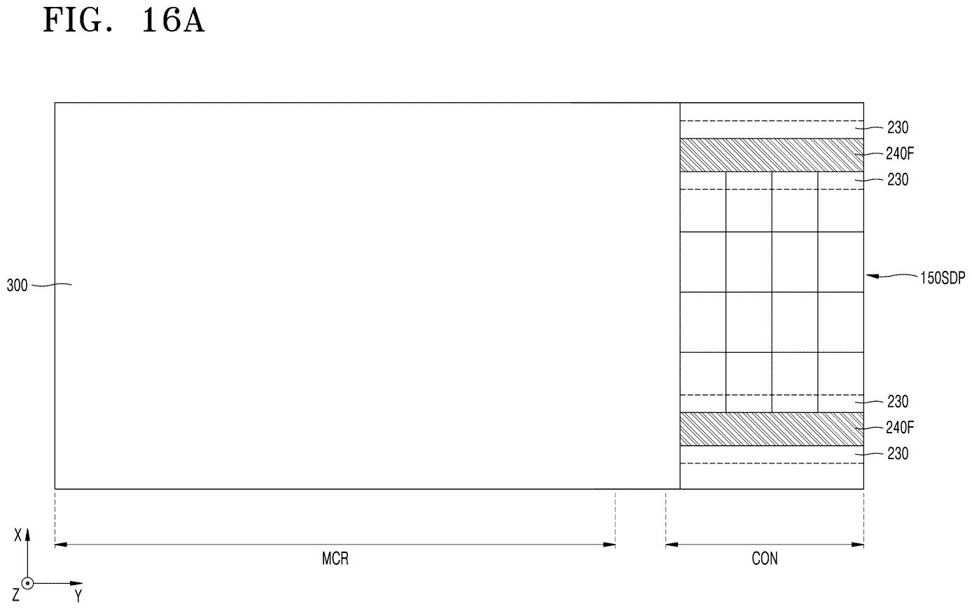

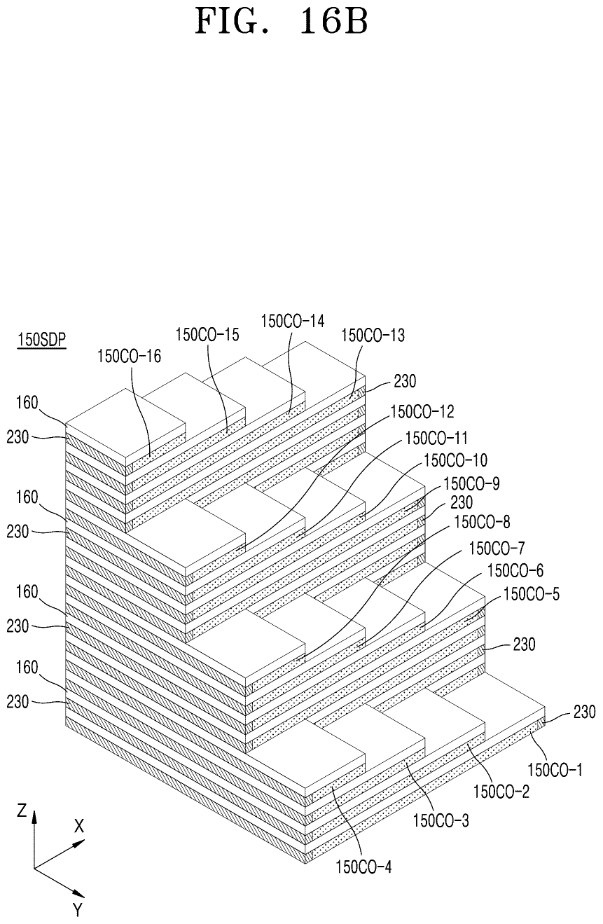

Referring to FIGS. 16A and 16B, the method of manufacturing a 3D DRAM may include an operation of forming the step region 150SDP in the first horizontal direction and the second horizontal direction. FIG. 16B is a perspective view of the step region 150SDP of FIG. 16A.

The step region 150SDP may include the connection mold layers 150CO-1, 150CO-2, . . . , and 150CO-16. The connection mold layers 150CO-1, 150CO-2, . . . , and 150CO-16 may have different widths in the horizontal direction. Furthermore, the second mold layers 160 disposed on the connection mold layers 150CO-1, 150CO-2, . . . , and 150CO-16, respectively, may also have different widths in the horizontal direction. In some embodiments, the step region 150SDP of FIG. 16B may be formed through the etching process performed on the step region 150SDP of FIG. 15B. As the etching process progresses, the horizontal area of the etch mask pattern may be gradually reduced in the first horizontal direction. The horizontal area of the etch mask pattern may be reduced through the trim process.

At least one of both side walls in the first horizontal direction of each of the connection mold layers 150CO-1, 150CO-2, . . . , and 150CO-16 may be surrounded by the third sacrificial layer 230. For example, both side walls in the first horizontal direction of each of the first to thirteenth connection mold layer 150CO-1, 150CO-2, . . . , and 150CO-13 may be covered by the third sacrificial layer 230. However, only one side wall in the first horizontal direction of each of the fourteenth to sixteenth connection mold layers 150CO-14, 150CO-15, and 150CO-16 may be covered by the third sacrificial layer 230, whereas the other side wall may be exposed to the outside.

In the descriptions described above with reference to FIGS. 15A, 15B, 16A, and 16B, although it is described that the steps are first formed in the second horizontal direction and then formed in the first horizontal direction, this is merely an example. By first firming the steps in the first horizontal direction and then in the second horizontal direction, the step region 150SDP of FIG. 16B may be formed.

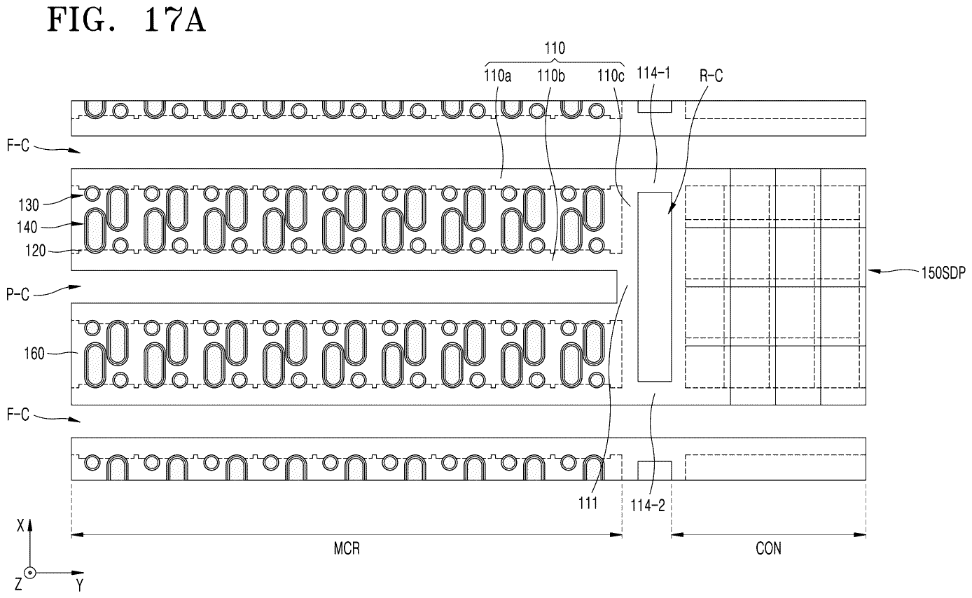

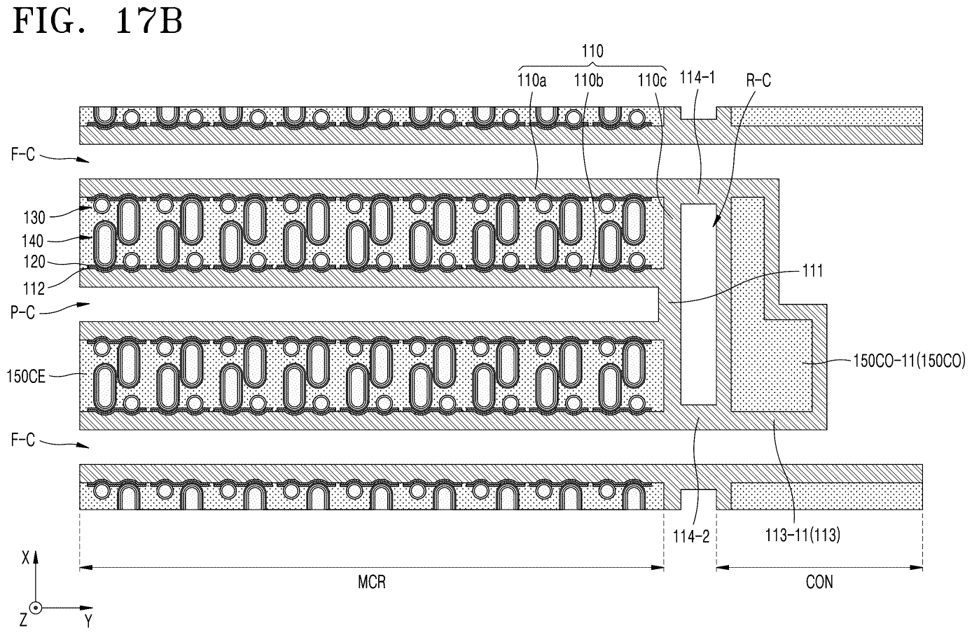

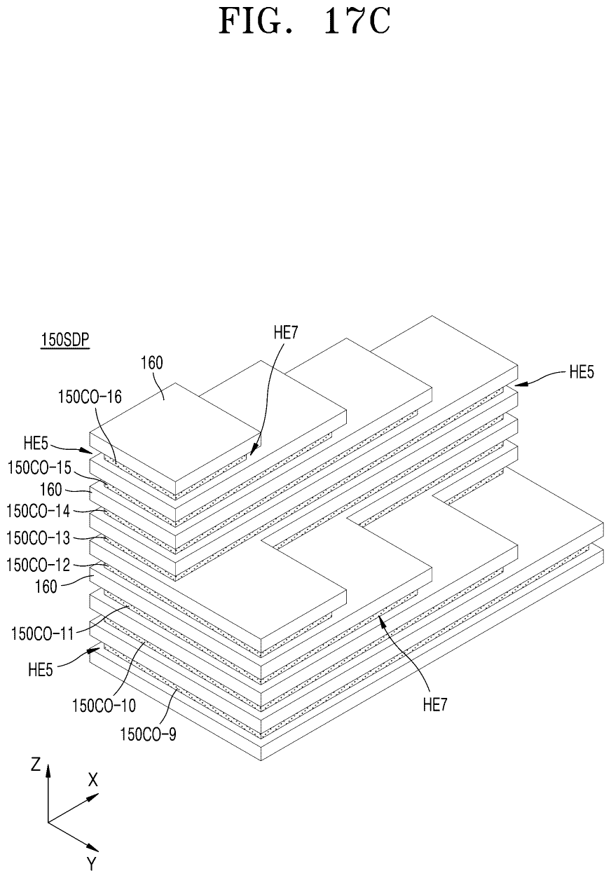

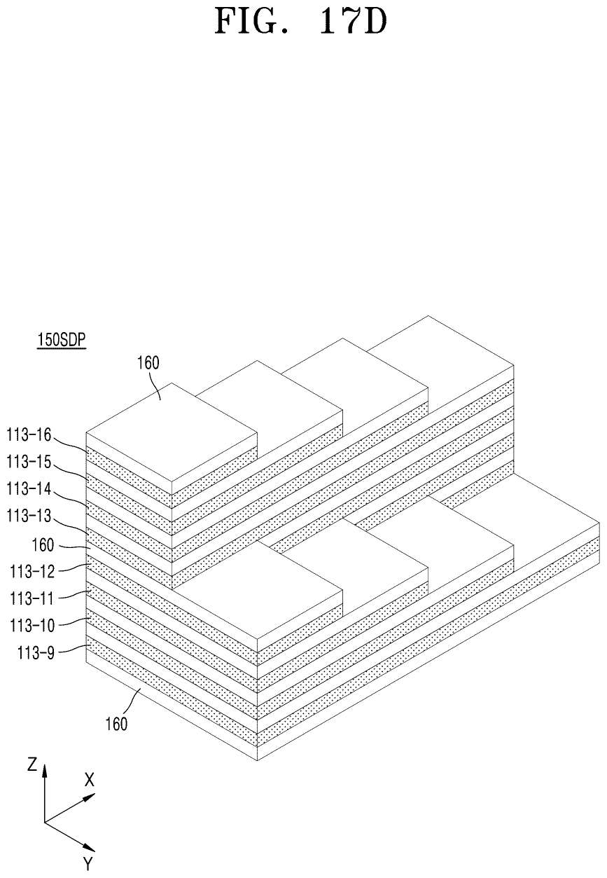

Referring to FIGS. 17A and 17B, the method of manufacturing a 3D DRAM may include an operation of forming the common word line 110, the word line connection portion 111, the word line pad 113, the first pad connection portion 114-1, and the second pad connection portion 114-2. FIG. 17B is a horizontal cross-sectional view of the mold structure MS cut in the horizontal direction at a vertical level where the eleventh connection mold layer 150CO-11 is disposed.

The common word line 110 may include the first part 110A and the second part 110B, both extending in the second horizontal direction and surrounded by the semiconductor layer 120, and the third part 110C extending in the first horizontal direction. The word line connection portion 111 may interconnect two common word lines 110 that are spaced apart from each other in the first horizontal direction. The first pad connection portion 114-1 and the second pad connection portion 114-2 may each interconnect the common word line 110 and the word line pad 113. The word line pad 113 may thinly surround the side wall of the connection mold layer 150CO.

The word line pads 113 may have different horizontal areas. For example, the eleventh word line pad 113-11 may surround the eleventh connection mold layer 150CO-11, and the twelfth word line pad 113-12 may surround the twelfth connection mold layer 150CO-12. In this example, as the twelfth connection mold layer 150CO-12 has a smaller horizontal area than the eleventh connection mold layer 150CO-11, the horizontal area of the twelfth word line pad 113-12 may be smaller than the horizontal area of the eleventh word line pad 113-11.

The common word line 110, the word line connection portion 111, the word line pad 113, and the first and second pad connection portions 114-1 and 114-2 may be integrally formed. The forming process of the common word line 110, the word line connection portion 111, the word line pad 113, and the first and second pad connection portions 114-1 and 114-2 is described in detail with reference to FIGS. 17C and 17D.

Referring to FIGS. 17A to 17D, before forming the word line pad 113, the protection layer 300 is first removed and then the fourth sacrificial layers 240F, 240P, and 240R are removed, and thus the full line-cut F-C, the partial line-cut P-C, and the region line-cut R-C may be formed again.

Then, a seventh horizontal expansion area HE7 may be formed. The seventh horizontal expansion area HE7 may be formed by removing a part of each of the connection mold layers 150CO-1, 150CO-2, . . . , and 150CO-16 from the outer surface of each of the connection mold layers 150CO-1, 150CO-2, . . . , and 150CO-16 exposed to the outside. In some embodiments, in the step region 150SDP, the outer surfaces of the connection mold layers 150CO-1, 150CO-2, . . . , and 150CO-16 and the outer surface of the second mold layer 160 may be exposed to the outside. In this example, only a part of each of the connection mold layers 150CO-1, 150CO-2, . . . , and 150CO-16 exposed to the outside may be removed through the wet etching process using etching selectivity between the connection mold layers 150CO-1, 150CO-2, . . . , and 150CO-16 and the second mold layer 160. In this example, the seventh horizontal expansion area HE7 may be a space surrounded by the side wall of the connection mold layer 150CO, the lower surface of the second mold layer 160 disposed on the connection mold layer 150CO, and the upper surface of the second mold layer 160 disposed under the connection mold layer 150CO.

Then, the third sacrificial layer 230 that fills the fourth horizontal expansion area HE4, the fifth horizontal expansion area HE5, and the sixth horizontal expansion area HE6 may be removed. By removing the third sacrificial layer 230, the fourth horizontal expansion area HE4, the fifth horizontal expansion area HE5, and the sixth horizontal expansion area HE6 may be formed again. The third sacrificial layer 230 may be removed through the etching process that removes the third sacrificial layer 230 from the outer surface of the third sacrificial layer 230 exposed through the full line-cut F-C, the partial line-cut P-C, and the region line-cut R-C. For example, the etching process may be a wet etching process using an etchant having high etching reactivity to the third sacrificial layer 230.

Then, by filling the fourth horizontal expansion area HE4, the fifth horizontal expansion area HE5, the sixth horizontal expansion area HE6, and the seventh horizontal expansion area HE7 with a metal material, the common word line 110, the word line connection portion 111, the word line pad 113, and the first and second pad connection portions 114-1 and 114-2 may be integrally formed.

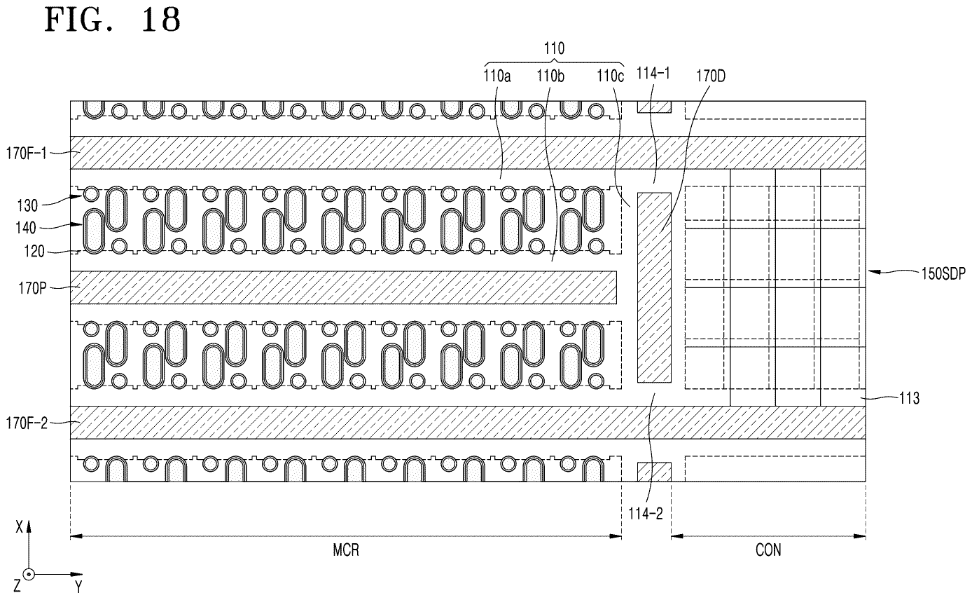

Referring to FIG. 18, the method of manufacturing a 3D DRAM may include an operation of forming the first and second stack separation insulating layers 170F-1 and 170F-2, the partial-separation insulating layer 170P, and the region separation insulating layer 170D. Two full line-cuts F-C spaced apart from each other in the first horizontal direction may be filled with the first and second stack separation insulating layers 170F-1 and 170F-2, respectively, the partial line-cut P-C may be filled with the partial-separation insulating layer 170P, and the region line-cut R-C may be filled with the region separation insulating layer 170D.

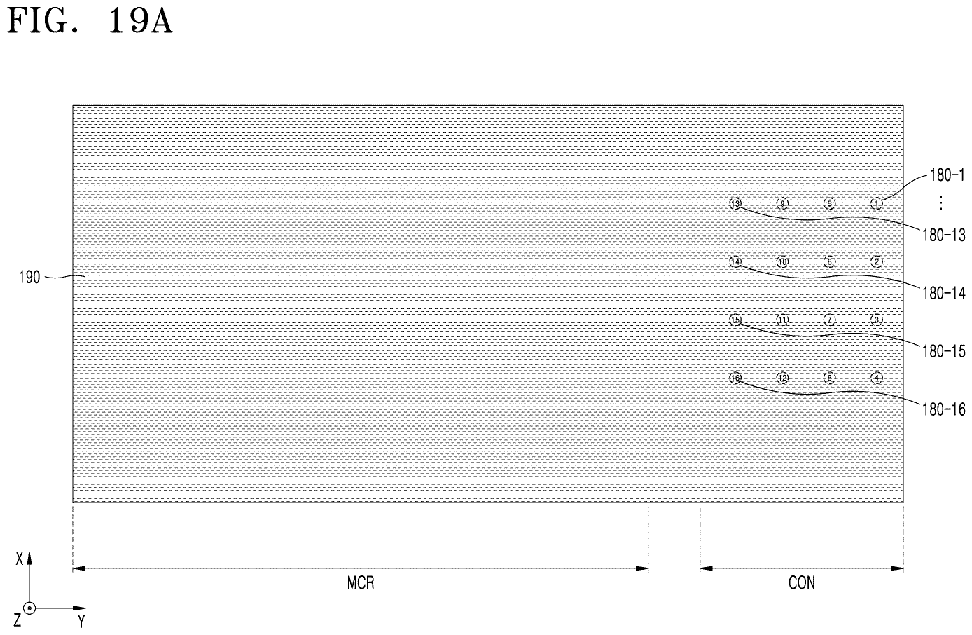

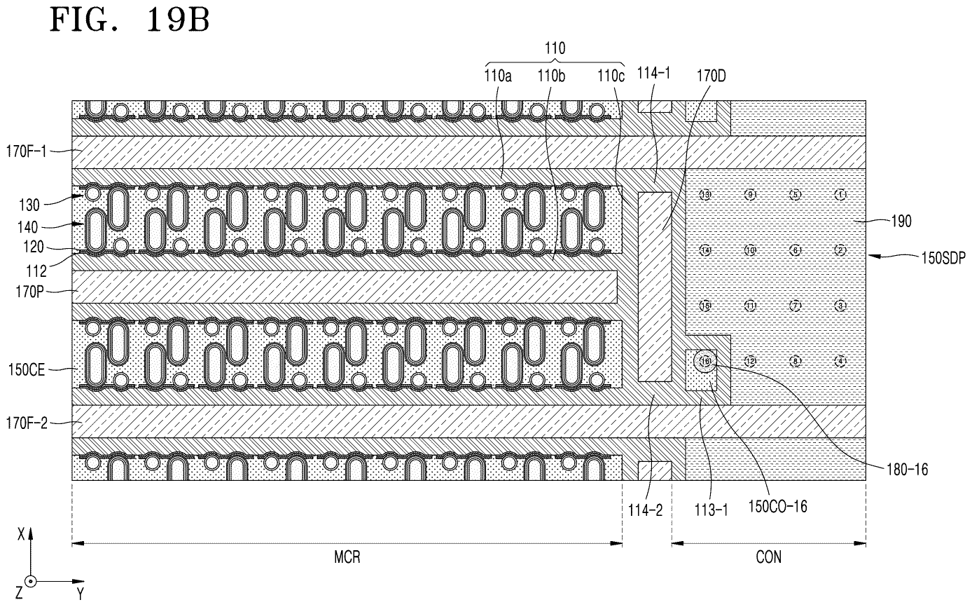

Referring to FIGS. 19A and 19B, the method of manufacturing a 3D DRAM may include an operation of forming the word-line contact plug 180. FIG. 19B is a horizontal cross-sectional view of the mold structure MS cut in the horizontal direction at a vertical level where the sixteenth connection mold layer 150CO-16 is disposed.

First, the cover insulating layer 190 that covers the step region 150SDP of the connection region CON may be formed. The cover insulating layer 190 may cover the memory cell region MCR. Then, the word-line contact plugs 180-1, 180-2, . . . , and 180-16 that penetrate the cover insulating layer 190 in the vertical direction may be formed. The word-line contact plugs 180-1, 180-2, . . . , and 180-16 may each be in contact with the inner wall of each of the word line pads 113-1, 113-2, . . . , and 113-16 disposed at different vertical levels in the step region 150SDP. From a horizontal perspective, the word-line contact plugs 180-1, 180-2, . . . , and 180-16 may be arranged in a 2D array shape first horizontal direction and in the second horizontal direction. As the word-line contact plugs 180-1, 180-2, . . . , and 180-16 are formed, a 3D DRAM according to an embodiment may be manufactured.

In the method of manufacturing a 3D DRAM according to an embodiment, the first to seventh horizontal expansion areas HE1, HE2, HE3, HE4, HE5, HE6, and HE7 may each have a relatively small ratio of the width in the horizontal direction to the height in the vertical direction. In other words, the aspect ratio of each of the first to seventh horizontal expansion areas HE1, HE2, HE3, HE4, HE5, HE6, and HE7 may not be relatively large, and thus, the difficulty of formation of each of the first to seventh horizontal expansion areas HE1, HE2, HE3, HE4, HE5, HE6, and HE7 through the etching process may not be relatively high. Furthermore, as each of the first to seventh horizontal expansion areas HE1, HE2, HE3, HE4, HE5, HE6, and HE7 has a low aspect ratio, the common word line 110, the semiconductor layer 120, the capacitor 140, the word line pad 113, the word line connection portion 111, and the first and second pad connection portions 114-1 and 114-2 may be easily formed with low step coverage process capability.

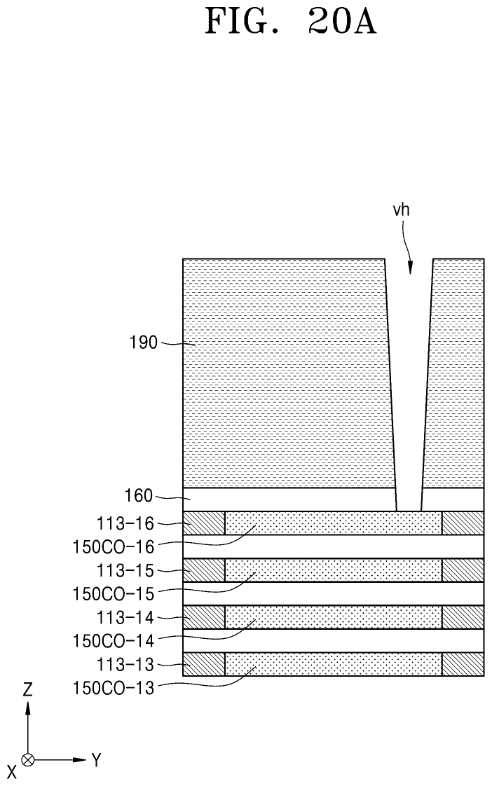

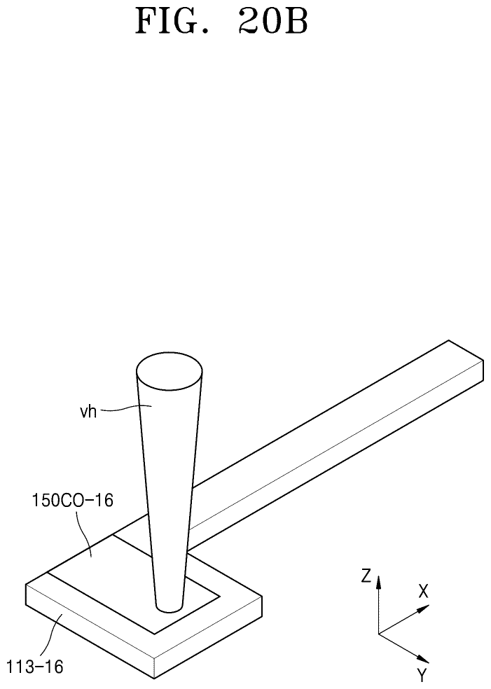

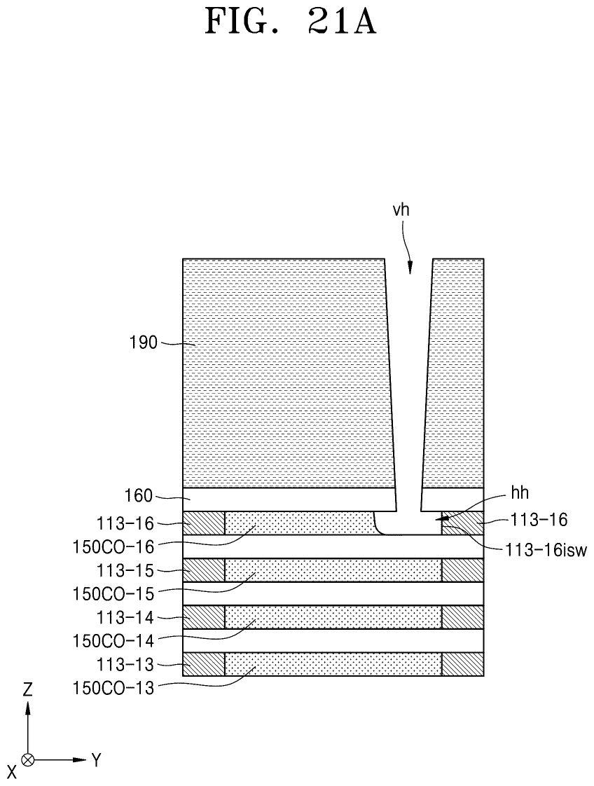

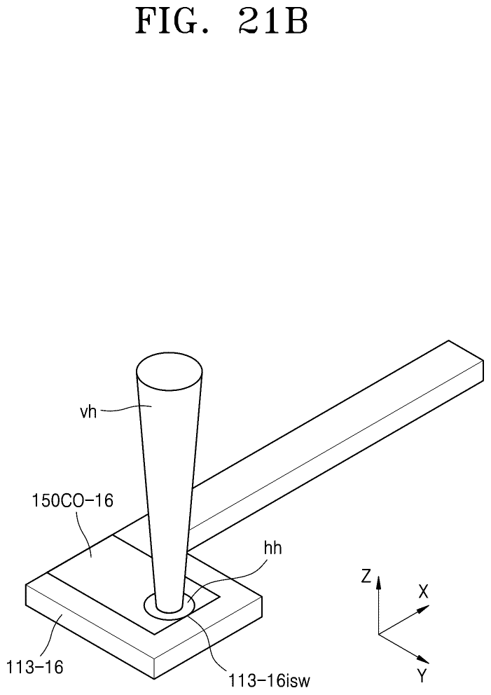

The word-line contact plugs 180-1, 180-2, . . . , and 180-16 may be formed through the sequential formation of a vertical hole (vh of FIG. 20A) and a horizontal hole (hh of FIG. 21A), which is described in detail with reference to the drawings described below.

FIGS. 20A, 20B, 21A, 21B, 22A, and 22B are perspective views and cross-sectional views schematically illustrating a process of a method of manufacturing a word-line contact plug, according to an embodiment. In the descriptions with reference to FIGS. 20A, 20B, 21A, 21B, 22A, and 22B, a method of manufacturing a word-line contact plug in contact with the sixteenth word line pad 113-16 is described as an example. This is merely for convenience of explanation, and a method of manufacturing a word-line contact plug in contact with the first to fifteenth word line pads 113-1, 113-2, . . . , and 113-15 may be performed based on the same method described below.

Referring to FIG. 20A and FIG. 20B, the vertical hole vh that penetrates the cover insulating layer 190 in the vertical direction may be formed. FIG. 20B is a perspective view schematically illustrating only the vertical hole vh, the sixteenth connection mold layer 150CO-16, and the sixteenth word line pad 113-16 of FIG. 20A.

The vertical hole vh may extend from the upper surface of the cover insulating layer 190 to the upper surface of the sixteenth connection mold layer 150CO-16 in the vertical direction. The vertical hole vh may penetrate the second mold layer 160 on the sixteenth connection mold layer 150CO-16 in the vertical direction. The vertical hole vh may expose the cover insulating layer 190, the second mold layer 160, and the sixteenth connection mold layer 150CO-16. In some embodiments, the vertical hole vh may penetrate a part of the sixteenth connection mold layer 150CO-16 in the vertical direction.

Referring to FIGS. 21A and 21B, the horizontal hole hh that penetrates the sixteenth connection mold layer 150CO-16 in the horizontal direction may be formed. FIG. 21B is a perspective view schematically illustrating only the vertical hole vh, the horizontal hole hh, the sixteenth connection mold layer 150CO-16, and the sixteenth word line pad 113-16 of FIG. 21A.

The horizontal hole hh may be formed through the etching process of removing a part of the sixteenth connection mold layer 150CO-16 from the outer surface of the sixteenth connection mold layer 150CO-16 exposed by the vertical hole vh. For example, the horizontal hole hh may be formed through the wet etching process using an etchant having high etching reactivity to the sixteenth connection mold layer 150CO-16. In this case, the etchant may have very low etching reactivity to the second mold layer 160 and the sixteenth word line pad 113-16.

The horizontal hole hh may expose an inner wall 113-16isw of the sixteenth word line pad 113-16, the sixteenth connection mold layer 150CO-16, and the second mold layer 160. The second mold layer 160 exposed by the horizontal hole hh may be the second mold layer 160 on the sixteenth connection mold layer 150CO-16 and the second mold layer 160 under the sixteenth connection mold layer 150CO-16.

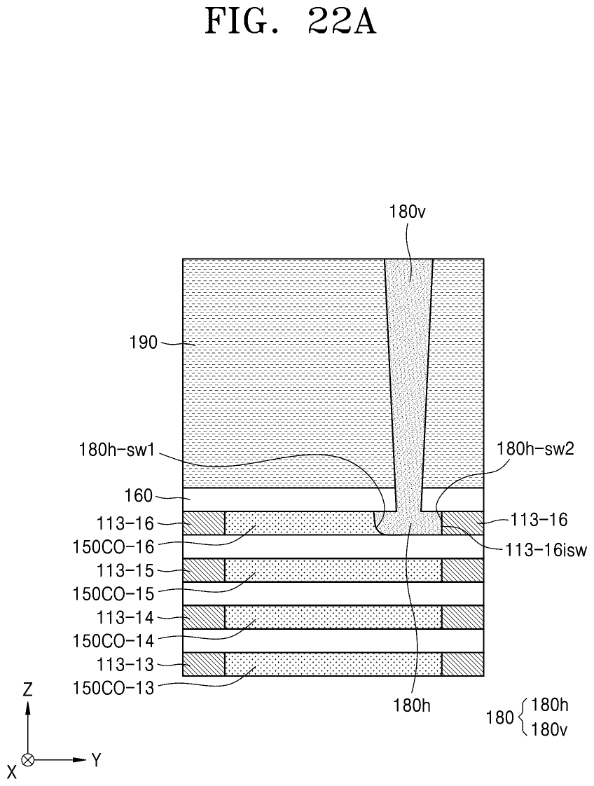

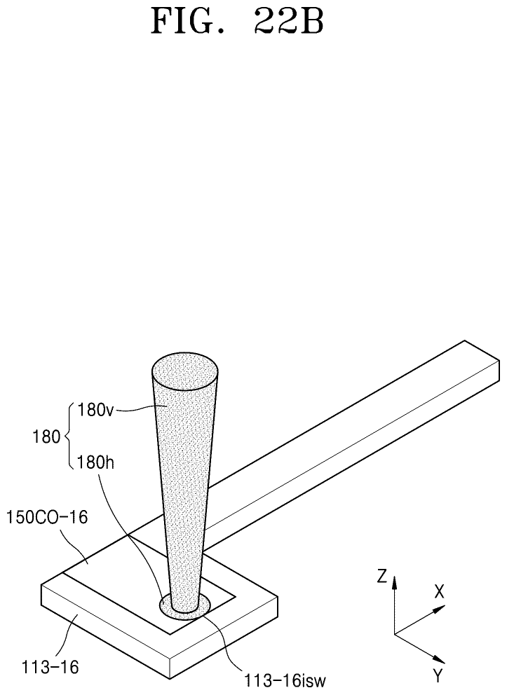

Referring to FIGS. 22A and 22B, the word-line contact plug 180 may be formed. FIG. 22B is a perspective view schematically illustrating only the word-line contact plug 180, the sixteenth connection mold layer 150CO-16, and the sixteenth word line pad 113-16 of FIG. 22A.

The word-line contact plug 180 may be formed by filling the vertical hole vh and the horizontal hole hh with a metal material. The word-line contact plug 180 may include a vertical portion 180v and a horizontal portion 180h. Of the entire side wall of the horizontal portion 180h, a first side wall 180h-sw1 may be covered by the sixteenth connection mold layer 150CO-16, and a second side wall 180h-sw2 that is a part of the entire side wall excluding the first side wall 180h-sw1 may be in contact with the inner wall 113-16isw of the sixteenth word line pad 113-16. Thus, the word-line contact plug 180 may be formed through the manufacturing process described above.

A method of manufacturing a 3D DRAM according to an embodiment comprises alternately stacking a first mold layer and a second mold layer on a substrate in the vertical direction, forming a capacitor and a bit line that penetrate the first mold layer and the second mold layer in the vertical direction and have a folding structure, forming a semiconductor layer in contact with the capacitor and the bit line, forming a full line-cut, a partial line-cut, and a region line-cut by removing a part of the first mold layer and a part of the second mold layer, forming a first horizontal expansion area that surrounds the full line-cut, a second horizontal expansion area that surrounds the partial line-cut, and a third horizontal expansion area that surrounds the region line-cut, forming a sacrificial layer that fills the first horizontal expansion area, the second horizontal expansion area, and the third horizontal expansion area, forming a step region by removing a part of the first mold layer and a part of the second mold layer, forming a fourth horizontal expansion area by removing a part of each of the first mold layers in the horizontal direction from the exposed outer surface of each of the first mold layers in the step region, removing the sacrificial layer that fills the first horizontal expansion area, the second horizontal expansion area, and the third horizontal expansion area, forming a common word line and a word line pad connected to each other by filling the first, second, third, and fourth horizontal expansion areas with a metal material, and forming word-line contact plugs in contact with an inner wall of each of the word line pads.

In some embodiments, in the forming of the common word line and the word line pad, the first horizontal expansion area may be a space exposed through the full line-cut, the second horizontal expansion area may be a space exposed through the partial line-cut, and the third horizontal expansion area may be a space exposed through the region line-cut.

In some embodiments, in the forming of the common word line and the word line pad, the fourth horizontal expansion area may be a space surrounded, in the step region, by a side wall of the first mold layer and upper surfaces and lower surfaces of the second mold layers.

In some embodiments, the forming of the common word line and the word line pad may comprise forming a word line connection portion between the full line-cut and the partial line-cut and forming a pad connection portion between the full line-cut and the region line-cut.

In some embodiments, the forming of the word-line contact plugs may comprise forming a stack separation insulating layer that fills the full line-cut, a partial-separation insulating layer that fills the partial line-cut, and a region separation insulating layer that fills the region line-cut, forming a cover insulating layer that covers the step region, and forming the word-line contact plugs that penetrate the cover insulating layer in the vertical direction.

In some embodiments, the forming of the word-line contact plugs may comprise forming a vertical hole that penetrates the cover insulating layer in the vertical direction, forming a horizontal hole that penetrates a connection mold layer from the vertical hole in the horizontal direction, and forming the word-line contact plugs by filling the vertical hole and the horizontal hole with a metal material, and the word line pad may cover a side wall of the connection mold layer.

In some embodiments, the forming of the horizontal hole may comprise exposing an inner wall of the word line pad by removing a part of the connection mold layer from a surface of the connection mold layer exposed by the vertical hole, and the horizontal hole may expose the inner wall of the word line pad, the connection mold layer, and the second mold layer.

In some embodiments, the forming of the capacitor and the bit line that penetrate the first mold layer and the second mold layer in the vertical direction and have a folding structure may comprise forming a first through-hole, a second through-hole, and a third through-hole that penetrate the first mold layer and the second mold layer, forming the capacitor within the third through-hole, and forming the bit line within the first through-hole, and the forming of the semiconductor layer in contact with the capacitor and the bit line may comprise forming a semiconductor layer in a fifth horizontal expansion area that expands from the second through-hole in the horizontal direction.

In some embodiments, the forming of the full line-cut, the partial line-cut, and the region line-cut may comprise forming a first full line-cut and a second full line-cut that are spaced apart from each other in the first horizontal direction and penetrate the first mold layer and the second mold layer in the vertical direction, forming the partial line-cut that penetrate the first mold layer and the second mold layer in the vertical direction between the first full line-cut and the second full line-cut and extend in a second horizontal direction perpendicular to the first horizontal direction, and the region line-cut that penetrates the first mold layer and the second mold layer in the vertical direction between the first full line-cut and the second full line-cut and extends in the first horizontal direction.

While the disclosure has been particularly shown and described with reference to embodiments thereof, it will be understood that various changes in form and details may be made therein without departing from the spirit and scope of the following claims.

What is claimed is:

1. A three-dimensional (3D) dynamic random access memory (DRAM) comprising: a substrate;
a first stack separation insulating layer and a second stack separation insulating layer both disposed on the substrate and spaced apart from each other in a first horizontal direction;
at least one partial-separation insulating layer, on the substrate, arranged between the first stack separation insulating layer and the second stack separation insulating layer in the first horizontal direction, and extending in a second horizontal direction perpendicular to the first horizontal direction;
a plurality of memory cell regions alternately arranged with the first stack separation insulating layer, the at least one partial-separation insulating layer, and the second stack separation insulating layer; and
a region separation insulating layer, on the substrate, arranged between the first stack separation insulating layer and the second stack separation insulating layer in the first horizontal direction, and extending in the first horizontal direction between the plurality of memory cell regions and a connection region, the plurality of memory cell regions and the connection region being arranged in the second horizontal direction,
wherein each of the plurality of memory cell regions comprises:
a first semiconductor layer and a second semiconductor layer spaced apart from each other in the first horizontal direction and facing each other;
a first bit line and a first capacitor both in contact with the first semiconductor layer, spaced apart from each other in the second horizontal direction;
a second bit line and a second capacitor both in contact with the second semiconductor layer, spaced apart from each other in the second horizontal direction;
a cell mold layer surrounding the first bit line, the first capacitor, the second bit line, and the second capacitor; and
a common word line surrounded by the first semiconductor layer and the second semiconductor layer and covering a side wall of the cell mold layer, and
the connection region comprises:
a connection mold layer;
a word line pad covering a side wall of the connection mold layer and having a liner shape; and
a word-line contact plug penetrating the connection mold layer and in contact with an inner wall of the word line pad.

2. The 3D DRAM of claim 1, further comprising a word line connection portion interconnecting the common word lines of two memory cell regions adjacent to each other among the plurality of memory cell regions,
wherein the word line connection portion is arranged between the region separation insulating layer and an adjacent partial-separation insulating layer in the second horizontal direction, and
the adjacent partial-separation insulating layer is one of the at least one partial-separation insulating layer, which is arranged between the two memory cell regions adjacent to each other in the first horizontal direction.

3. The 3D DRAM of claim 1, further comprising:
a first pad connection portion that interconnects the common word line of a first memory cell region and the word line pad of the connection region; and
a second pad connection portion that interconnects the common word line of a second memory cell region and the word line pad of the connection region,
wherein the first memory cell region is a closest memory cell region to the first stack separation insulating layer, among the plurality of memory cell regions, and
the second memory cell region is a closest memory cell region to the second stack separation insulating layer, among the plurality of memory cell regions.

4. The 3D DRAM of claim 3, wherein the first pad connection portion is arranged between the first stack separation insulating layer and the region separation insulating layer in the first horizontal direction, and
the second pad connection portion is arranged between the second stack separation insulating layer and the region separation insulating layer in the first horizontal direction.

5. The 3D DRAM of claim 1, wherein the connection region further comprises a cover insulating layer that covers an upper surface of the connection mold layer,
the word-line contact plug comprises:
a vertical portion that penetrates the cover insulating layer and the connection mold layer in a vertical direction; and
a horizontal portion that extends from the vertical portion in a horizontal direction,
the horizontal portion penetrates the connection mold layer in the horizontal direction, and
a partial side wall among an entire side wall of the horizontal portion is in contact with the inner wall of the word line pad.

6. The 3D DRAM of claim 5, wherein the connection mold layer covers a remaining side wall among the entire side wall of the horizontal portion.

7. The 3D DRAM of claim 1, wherein the region separation insulating layer comprises a first side wall and a second side wall facing each other,
the first side wall of the region separation insulating layer is in contact with the common word line of each of the plurality of memory cell regions, and
the second side wall of the region separation insulating layer is in contact with the word line pad of the connection region.

8. The 3D DRAM of claim 1, wherein a width of each of the at least one partial-separation insulating layer in the second horizontal direction is less than a width of the cell mold layer in the second horizontal direction.

9. The 3D DRAM of claim 1, wherein a width of the region separation insulating layer in the first horizontal direction is greater than or equal to a first width, and
the first width is a sum of a value obtained by adding widths of the cell mold layers of the plurality of memory cell regions and widths of the at least one partial-separation insulating layer in the first horizontal direction.

10. A three-dimensional (3D) dynamic random access memory (DRAM) comprising: a substrate;
a first stack separation insulating layer and a second stack separation insulating layer spaced apart from each other in a first horizontal direction, on the substrate;
at least one partial-separation insulating layer, on the substrate, arranged between the first stack separation insulating layer and the second stack separation insulating layer in the first horizontal direction, and extending in a second horizontal direction perpendicular to the first horizontal direction;
a plurality of memory cell regions alternately arranged with the first stack separation insulating layer, the at least one partial-separation insulating layer, and the second stack separation insulating layer;
a first region separation insulating layer, on the substrate, extending from the first stack separation insulating layer in the first horizontal direction and arranged between the plurality of memory cell regions and a connection region, the plurality of memory cell regions and the connection region being arranged in the second horizontal direction; and
a second region separation insulating layer extending from the second stack separation insulating layer in the first horizontal direction and arranged between the plurality of memory cell regions and the connection region,
wherein each of the plurality of memory cell regions comprises:
a first semiconductor layer and a second semiconductor layer spaced apart from each other in the first horizontal direction and facing each other;
a first bit line and a first capacitor both in contact with the first semiconductor layer, spaced apart from each other in the second horizontal direction;
a second bit line and a second capacitor both in contact with the second semiconductor layer, spaced apart from each other in the second horizontal direction;
a cell mold layer surrounding the first bit line, the first capacitor, the second bit line, and the second capacitor; and
a common word line surrounded by the first semiconductor layer and the second semiconductor layer and covering a side wall of the cell mold layer, and
the connection region comprises:
a connection mold layer;
a word line pad having a liner shape surrounding a side wall of the connection mold layer; and
a word-line contact plug penetrating the connection mold layer and in contact with an inner wall of the word line pad.

11. The 3D DRAM of claim 10, further comprising a word line connection portion interconnecting the common word lines of two memory cell regions adjacent to each other among the plurality of memory cell regions.

12. The 3D DRAM of claim 11, further comprising a dummy mold layer arranged between the first region separation insulating layer and the second region separation insulating layer in the first horizontal direction,
wherein the word line connection portion is arranged between an adjacent partial-separation insulating layer and the dummy mold layer in the second horizontal direction, and
the adjacent partial-separation insulating layer is one of the at least one partial-separation insulating layer, which is arranged between the two memory cell regions adjacent to each other in the first horizontal direction.

13. The 3D DRAM of claim 12, further comprising:
a first pad connection portion that interconnects the common word line of a first memory cell region and the word line pad of the connection region; and
a second pad connection portion that interconnects the common word line of a second memory cell region and the word line pad of the connection region,
wherein the first memory cell region and the second memory cell region are the two memory cell regions that are arranged closest to the dummy mold layer among the plurality of memory cell regions.

14. The 3D DRAM of claim 13, wherein the first pad connection portion is arranged between the first region separation insulating layer and the dummy mold layer in the first horizontal direction, and
the second pad connection portion is arranged between the second region separation insulating layer and the dummy mold layer in the first horizontal direction.

15. The 3D DRAM of claim 10, wherein the connection region further comprises a cover insulating layer that covers an upper surface of the connection mold layer,
the word-line contact plug comprises:
a vertical portion that penetrates the cover insulating layer and the connection mold layer in a vertical direction; and
a horizontal portion that extends from the vertical portion in a horizontal direction,
the horizontal portion penetrates the connection mold layer in the horizontal direction, and
a partial side wall among an entire side wall of the horizontal portion is in contact with the inner wall of the word line pad.

16. The 3D DRAM of claim 15, wherein the connection mold layer covers a remaining side wall among the entire side wall of the horizontal portion.

17. The 3D DRAM of claim 10, wherein each of the first and second region separation insulating layers comprises a first side wall and a second side wall facing each other,
the first side wall of each of the first and second region separation insulating layers is in contact with the common word line of each of the plurality of memory cell regions, and
the second side wall of each of the first and second region separation insulating layers is in contact with the word line pad of the connection region.

18. The 3D DRAM of claim 10, wherein a width of each of the at least one partial-separation insulating layer in the second horizontal direction is less than a width of the cell mold layer in the second horizontal direction.

19. A three-dimensional (3D) dynamic random access memory (DRAM) comprising:
a substrate;
a plurality of memory cell regions;
a first stack separation insulating layer and a second stack separation insulating layer spaced apart from each other in a first horizontal direction, on the substrate;
at least one partial-separation insulating layer, on the substrate, arranged between the first stack separation insulating layer and the second stack separation insulating layer in the first horizontal direction, and extending between the plurality of memory cell regions in a second horizontal direction perpendicular to the first horizontal direction;
a region separation insulating layer, on the substrate, arranged between the first stack separation insulating layer and the second stack separation insulating layer, and extending in the first horizontal direction between the plurality of memory cell regions and a connection region, the plurality of memory cell regions and the connection region being arranged in the second horizontal direction,
wherein each of the plurality of memory cell regions comprises:
a first semiconductor layer and a second semiconductor layer spaced apart from each other in the first horizontal direction and facing each other;
a first bit line and a first capacitor both in contact with the first semiconductor layer, spaced apart from each other in the second horizontal direction;
a second bit line and a second capacitor both in contact with the second semiconductor layer, spaced apart from each other in the second horizontal direction;
a cell mold layer surrounding the first bit line, the first capacitor, the second bit line, and the second capacitor; and
a common word line surrounded by the first semiconductor layer and the second semiconductor layer and covering a side wall of the cell mold layer,
the connection region comprises:
(M*N) connection mold layers arranged in M rows in the first horizontal direction, where M is a natural number greater than or equal to 2, and N columns in the second horizontal direction, where N is a natural number greater than or equal to 2;
(M*N) word line pads surrounding a side wall of each of the (M*N) connection mold layers, spaced apart from each other in a vertical direction, and having a liner shape; and
(M*N) word-line contact plugs in contact with inner walls of the (M*N) word line pads, and arranged in a two-dimensional array shape in the first horizontal direction and the second horizontal direction, and
a connection layer number of each of the (M*N) word-line contact plugs decreases in a staircase manner in the first horizontal direction and the second horizontal direction.

20. The 3D DRAM of claim 19, wherein the connection region further comprises a cover insulating layer that covers upper surfaces of the (M*N) connection mold layers,
each of the (M*N) word-line contact plugs comprises:
a vertical portion that penetrates the cover insulating layer in the vertical direction; and
a horizontal portion that extends from a lower portion of the vertical portion in a horizontal direction,
a partial side wall among an entire side wall of the horizontal portion of each of the (M*N) word-line contact plugs is in contact with the inner wall of each of the (M*N) word line pads, and
a remaining side wall among the entire side wall of the horizontal portion of each of the (M*N) word-line contact plugs is covered by each of the (M*N) connection mold layers.
